(19) United States
(12) Patent Application Publication
(10) Pub. No.: US 2026/0074672 A1
(43) Pub. Date: Mar. 12, 2026

(54) VIBRATION DEVICE AND METHOD FOR MANUFACTURING VIBRATION DEVICE

(71) Applicant: KYOCERA Corporation, Kyoto-shi, Kyoto (JP)

(72) Inventors: Yoshiyuki KAWAGUCHI, Soraku-gun, Kyoto (JP); Shigeo AONO, Soraku-gun, Kyoto (JP)

(73) Assignee: KYOCERA Corporation, Kyoto-shi, Kyoto (JP)

(21) Appl. No.: 19/106,556

(22) PCT Filed: Aug. 4, 2023
(86) PCT No.: PCT/JP2023/028524

§ 371 Date: Feb. 25, 2025

(30) Foreign Application Priority Data
Aug. 30, 2022 (WO) PCT/JP2022/032580

(51) Int. Cl. H03H 9/19; H03H 9/05

(52) U.S. Cl. CPC H03H 9/19; H03H 9/059

(57) ABSTRACT

A vibration device includes: first and second substrates; an intermediate layer; and an excitation electrode. The first substrate includes a first surface. The second substrate includes a second surface facing the first surface. The intermediate layer is located between the first and second surfaces. The first surface includes a first recess. The intermediate layer includes a vibration portion and a frame portion. The vibration portion includes an excitation portion at which the excitation electrode is located. The excitation portion faces the first recess. The frame portion surrounds the vibration portion and is joined to the first and second surfaces. The frame portion includes a layer of the same material as included in the vibration portion. An entire periphery of an outer edge of the vibration portion is away from the frame portion. The vibration portion is joined to an outer peripheral region of the first recess on the first surface.

### TECHNICAL FIELD

The present disclosure relates to a vibration device such as a quartz crystal vibrator and a method of manufacturing the vibration device.

### BACKGROUND OF INVENTION

In a known quartz crystal vibrator of so-called wafer-level packaging (WLP), a plate-shaped base, a quartz crystal substrate, and a plate-shaped lid are stacked in this order (for example, Patent Literatures 1 to 4). The quartz crystal substrate includes a vibration portion and a frame portion surrounding the vibration portion in plan view. The vibration portion is provided with excitation electrodes for vibrating the vibration portion. The frame portion is joined to the base and the lid. The base, the frame portion, and the lid compose a package for containing the vibration portion in a sealed space.

In Patent Literatures 1 to 3, part or all of the outer periphery of the vibration portion is connected to the frame portion. With this configuration, the vibration portion is supported by the package composed of the base, the frame portion, and the lid.

In Patent Literature 4, the vibration portion is away from the frame portion throughout its entire periphery, unlike Patent Literatures 1 to 3. Then, the vibration portion is joined to the upper surface of the base with bumps interposed therebetween. With this configuration, the vibration portion is supported by the package, being floated from the upper surface of the base.

### CITATION LIST

### Patent Literature

Patent Literature 1: Japanese Unexamined Patent Application Publication No. 2000-138554
Patent Literature 2: International Publication No. 2020/137830
Patent Literature 3: Japanese Unexamined Patent Application Publication No. 2022-38150
Patent Literature 4: International Publication No. 2015/162958

### SUMMARY

In an aspect of the present disclosure, a vibration device includes: a first substrate; a second substrate; an intermediate layer; and an excitation electrode. The first substrate includes a first surface. The second substrate includes a second surface facing the first surface. The intermediate layer is located between the first surface and the second surface. The first surface includes a first recess. The intermediate layer includes a vibration portion and a frame portion. The vibration portion includes an excitation portion at which the excitation electrode is located. The excitation portion faces the first recess. The frame portion surrounds the vibration portion in plan view and is joined to the first surface and the second surface. The frame portion includes a layer composed of a same material as a layer included in the vibration portion. An entire periphery of an outer edge of the vibration portion is away from the frame portion. The vibration portion is joined to an outer peripheral region of the first recess on the first surface.

A method of manufacturing the vibration device includes: first joining; etching; and second joining. In the first joining, the intermediate layer including the vibration portion and the frame portion in an integrated form is joined to the first surface including the first recess. In the etching, the intermediate layer is etched after the first joining, and the entire periphery of the outer edge of the vibration portion is separated from the frame portion. In the second joining, the second surface is joined to the intermediate layer after the etching.

### BRIEF DESCRIPTION OF THE DRAWINGS

FIG. 1 is an exploded perspective view illustrating the configuration of a quartz crystal vibrator according to an embodiment.

FIG. 2 is an exploded perspective view of the quartz crystal vibrator in FIG. 1 from a direction different from the viewing direction in FIG. 1.

FIG. 3 is a cross-sectional view taken along line III-III in FIG. 1.

FIG. 4 is a cross-sectional view of another example of metal layers, in the same manner as FIG. 3.

FIG. 5 is a perspective view illustrating the configuration of a vibration portion of the quartz crystal vibrator in FIG. 1.

FIG. 6A is a cross-sectional view taken along line VIa-VIa in FIG. 5, FIG. 6B is a cross-sectional view taken along line VIb-VIb in FIG. 5, and FIG. 6C is a cross-sectional view illustrating another example of the electrical connection between the front and back of the vibration portion.

FIG. 7 is a plan view illustrating another example of the relationship between a first recess and the vibration portion.

FIG. 8A is a plan view illustrating still another example of the relationship between the first recess and the vibration portion, and FIG. 8B is a cross-sectional view taken along line VIIIb-VIIIb in FIG. 8A.

FIG. 9 is a plan view of another example of a first substrate of the quartz crystal vibrator.

FIG. 10 is an enlarged view of region X in FIG. 2.

FIG. 11 is an enlarged view of a portion including a second pad electrode in FIG. 3.

FIGS. 12A, 12B, and 12C are schematic cross-sectional views illustrating an example of a method of manufacturing the quartz crystal vibrator in FIG. 1.

FIGS. 13A, 13B, and 13C are cross-sectional views illustrating the subsequent processes after FIG. 12C.

FIGS. 14A, 14B, and 14C are cross-sectional views illustrating steps performed in parallel with the processes in FIG. 12A and the like.

FIGS. 15A, 15B, and 15C are cross-sectional views illustrating the subsequent processes after FIGS. 13C and 14C.

FIG. 16 is a plan view illustrating still another example of the relationship between the first recess and the vibration portion.

FIG. 17A is a plan view of another example of an intermediate layer and metal layers, and FIG. 17B is a plan view of another example of a second substrate and metal layers corresponding to FIG. 17A.

FIG. 18 is an exploded perspective view illustrating another example of a support structure of the vibration portion.

FIG. 19 is an exploded perspective view of the quartz crystal vibrator in FIG. 18 from a direction different from the viewing direction in FIG. 18.

FIG. 20 is a cross-sectional view taken along line XX-XX in FIG. 18.

### DESCRIPTION OF EMBODIMENTS

Hereinafter, an embodiment of the present disclosure will be described with reference to drawings. Note that the figures used in the following description are schematic. Hence, for example, the ratios of dimensions in the drawings are not necessarily consistent with those of an actual one. The ratios of dimensions and the like are sometimes not consistent among the drawings. In some cases, specific shapes, dimensions, and/or the like are exaggerated, and details are omitted. However, the above explanation is not intended to deny that actual shapes and/or dimensions may be set to the same as those in the drawings, and that features of shapes and/or dimensions may be extracted from the drawings.

In the description of multiple configurations, the subsequent configurations basically describe only the differences from the previously described configurations. The items not specifically referred to may be considered to be the same as and/or similar to those in the configurations previously described or may be inferred from the configurations previously described. In multiple configurations, constituents corresponding to each other are sometimes denoted by the same symbols for convenience even if they have some differences. In contrast, the same constituents are sometimes denoted by different symbols for convenience of explanation. In the description of the embodiment, description is sometimes provided for convenience, without notification, on the assumption that the configuration (the shapes, dimensions, and the like of constituents) of a vibration device is illustrated in a figure as an example.

### Overview of Embodiment

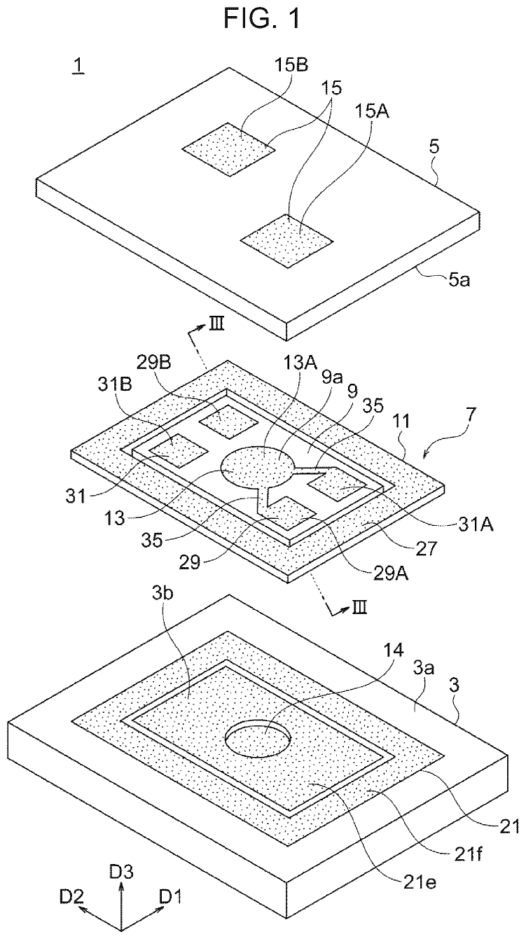

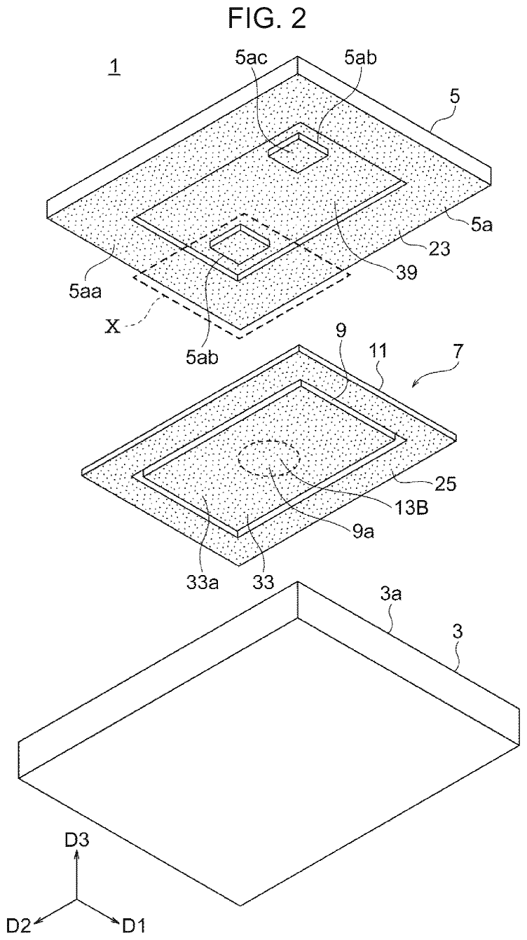

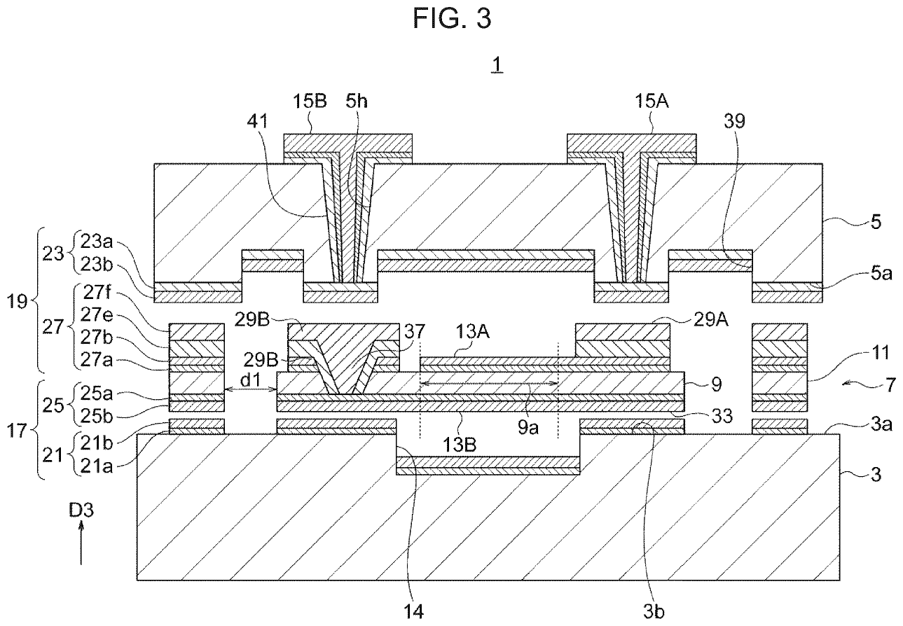

FIGS. 1 and 2 are exploded perspective views illustrating the configuration of a quartz crystal vibrator 1 (an example of a vibration device) according to an embodiment. FIG. 3 is a cross-sectional view taken along line III-III in FIG. 1. In FIGS. 1 and 2, the hatching indicates that relatively thin layers (for example, metal layers (conductor layers)) are located (in other words, it does not indicate cross sections).

The drawings include a Cartesian coordinate system D1D2D3 for convenience. In the following description, “plan view” or “perspective plan view” denotes viewing in the D3 direction unless otherwise specified. The vibrator 1 can be used with any face facing upward. However, for convenience, terms such as “immediately below” and “immediately above” are sometimes used on the assumption that the +D3 direction is the upward direction.

The quartz crystal vibrator 1 (hereinafter sometimes simply referred to as the “vibrator 1”) is an electronic component including three layers illustrated in FIGS. 1 to 3, stacked together. When an alternating current voltage is applied to the vibrator 1, a vibration portion 9 contained in the vibrator 1 vibrates. This vibration is used, for example, to generate an oscillation signal. In the oscillation signal, for example, the signal level (for example, the voltage) vibrates at a constant frequency.

The vibrator 1 includes a first substrate 3, an intermediate layer 7, and a second substrate 5 in this order from the −D3 side as the three layers mentioned above. The intermediate layer 7 includes, in plan view, the vibration portion 9 mentioned above and a frame portion 11 surrounding the vibration portion 9. The frame portion 11 and the vibration portion 9 are composed of the same material. In a higher concept in consideration of a configuration in which the frame portion 11 and/or the vibration portion 9 includes a layered structure, the frame portion 11 includes a layer composed of the same material as a layer included in the vibration portion 9. The vibration portion 9 and the frame portion 11 are formed by, for example, etching a layer (member) integrally formed by using the same material.

The front and back (the +D3 side surface and the −D3 side surface) of the vibration portion 9 are provided with a first excitation electrode 13A and a second excitation electrode 13B (hereinafter, these are sometimes not distinguished and referred to as the “excitation electrodes 13”), respectively, for exciting the vibration portion 9. Note that in the example in FIG. 2, the entire −D3 side surface of the vibration portion 9 is covered with a metal layer (a multifunctional electrode 33). In such a configuration, for example, the region (indicated by a dashed line in FIG. 2) of the metal layer overlapping the first excitation electrode 13A on the +D3 side can be regarded as the second excitation electrode 13B on the −D3 side.

The region of the vibration portion 9 overlapping the paired excitation electrodes 13 in plan view is referred to as an excitation portion 9a. In FIGS. 1 and 2, the excitation portion 9a is not illustrated because it is behind the paired excitation electrodes 13. Hence, the symbol of the excitation portion 9a is assigned to a position overlapping the excitation electrodes 13 for convenience. Similarly, the symbols indicating the first substrate 3, the second substrate 5, and the intermediate layer 7 are sometimes assigned to conductor layers stacked on them for convenience. The excitation portion 9a is the region designed to vibrate. The vibration of the excitation portion 9a is used to generate an oscillation signal as mentioned above.

The frame portion 11 is joined to a first surface 3a of the first substrate 3 facing the intermediate layer 7 (the +D3 side) along the entire periphery of the frame portion 11. The frame portion 11 is joined to a second surface 5a of the second substrate 5 facing the intermediate layer 7 (the −D3 side) along the entire periphery of the frame portion 11. This forms a sealed space surrounded by the first substrate 3, the frame portion 11, and the second substrate 5. In other words, the vibration portion 9 is enclosed. The inside of the sealed space (the surroundings of the vibration portion 9) is, for example, in a vacuum state (which is actually a state lower than the atmospheric pressure) or a state in which an appropriate gas (for example, an inert gas such as nitrogen) is present.

The first surface 3a includes a first recess 14. The vibration portion 9 is stacked on the first surface 3a such that the excitation portion 9a faces the first recess 14. The vibration portion 9 (more specifically, a region outside the excitation portion 9a) is joined to an outer peripheral region 3b which is outside the first recess 14 on the first surface 3a. The entire outer edge of the vibration portion 9 is away from the frame portion 11.

As described above, the portion related to vibration (the vibration portion 9) and the portion related to sealing (the frame portion 11) are completely separated. This, for example, reduces the probability that the vibration of the vibration portion 9 is leaked to the frame portion 11. The excitation portion 9a of the vibration portion 9 is away from the first surface 3a because of the presence of the first recess 14. This makes the vibration of the excitation portion 9a easier. This, for example, reduces the need for conductive bumps to lift the excitation portion 9a away from the first surface 3a. Since the materials of at least part of the layers are common between the frame portion 11 and the vibration portion 9, the frame portion 11 and the vibration portion 9, for example, can be formed by using layers (a member) having an integrated form. In this case, for example, the layers having an integrated form mentioned above can be formed to be parallel to the first substrate 3, and this will reduce the warp and/or deflection of the vibration portion 9, stabilizing the characteristics of the vibrator 1. For example, the vibration portion 9 may be supported (jointed) at any position in the outer periphery of the first recess 14, and this increases the degree of freedom in design. For example, the vibration portion 9 may be joined to the outer peripheral region 3b along the entire periphery of the first recess 14. In addition, the portion of the vibration portion 9 outside the region facing the first recess 14 may be joined to the outer peripheral region 3b in its entirety. In such a case, for example, the warp and/or deflection of the vibration portion 9 will be reduced, and the characteristics of the vibrator 1 will be stable.

Note that the area of the portion of the vibration portion 9 facing the first recess 14 in plan view may be less than the area of the outer peripheral region 3b in plan view. For example, it may be a half or less. The outer peripheral region 3b with this configuration can hold the vibration portion 9 stably.

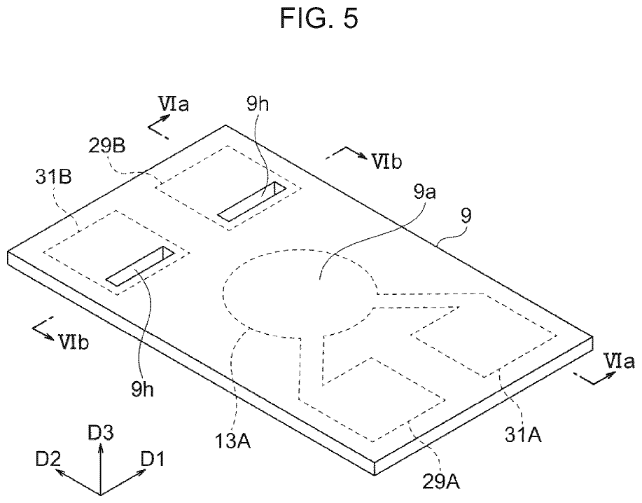

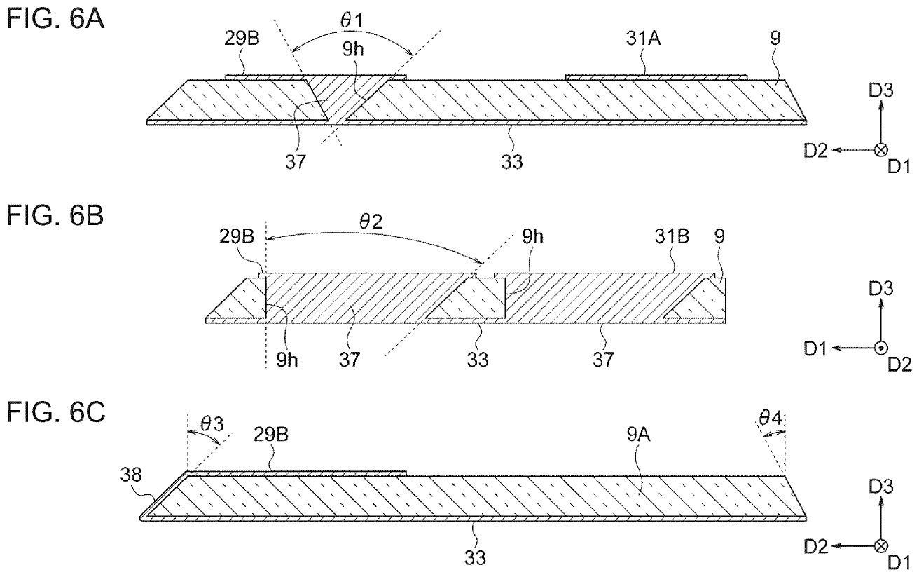

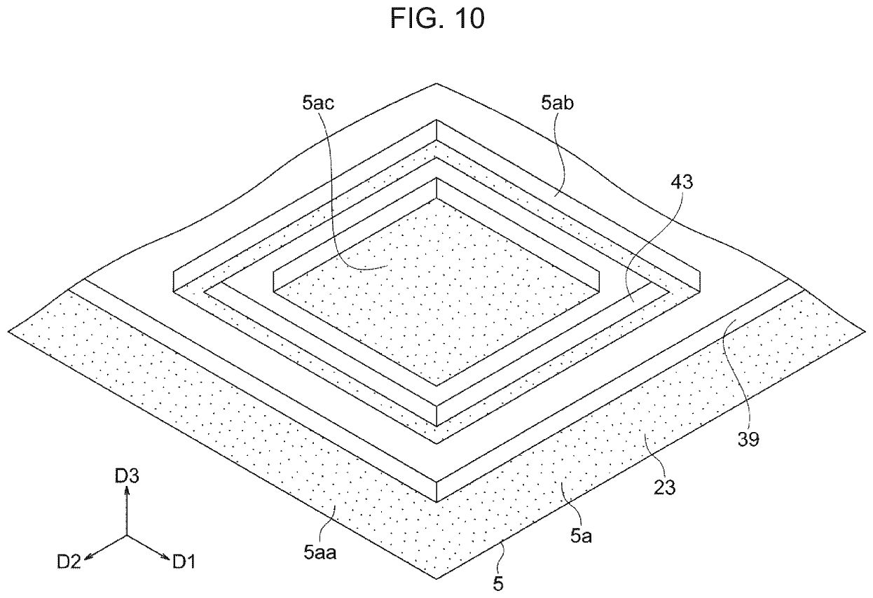

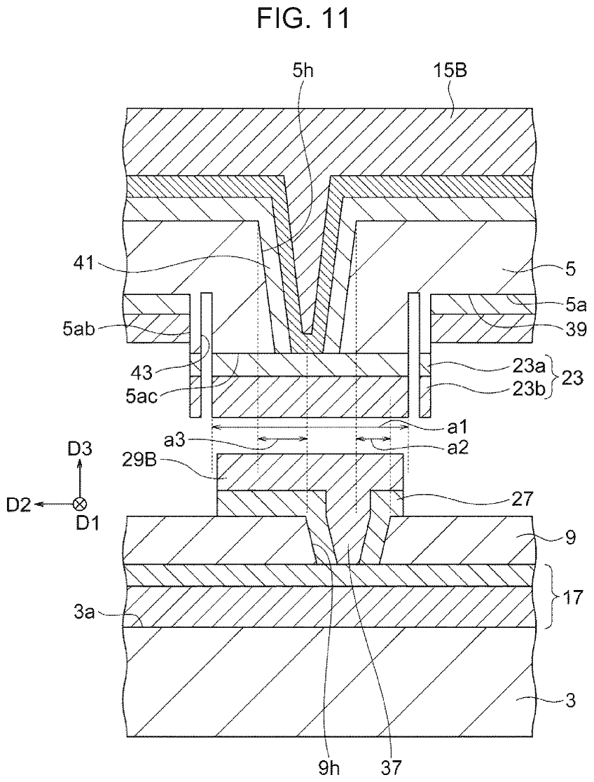

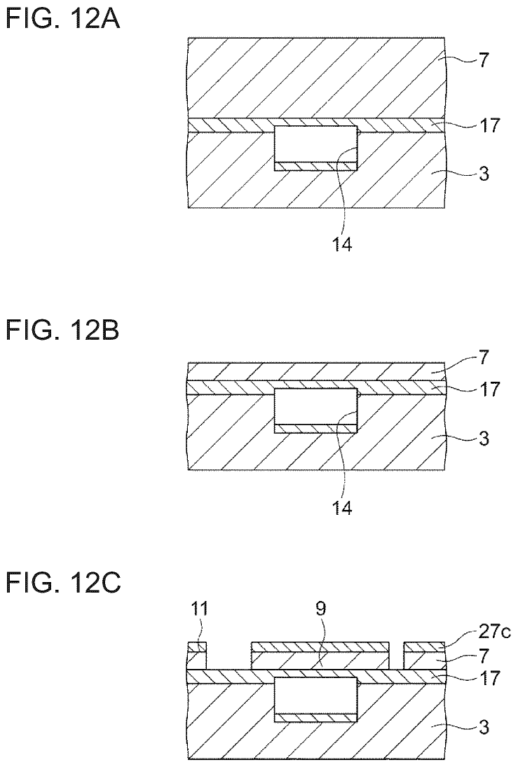

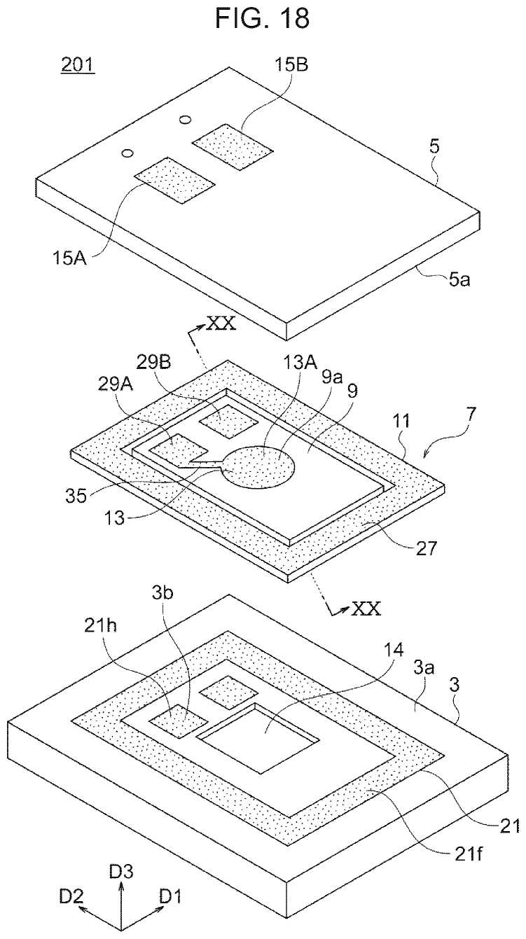

An overview of the embodiment is as mentioned above. In the following, the embodiment will be described in approximately the following order.
1. Overview of Vibrator (FIGS. 1 to 3)
   1.1. Shape and Dimensions of Vibrator
   1.2. Mounting Configuration of Vibrator
   1.3. Joining of First Substrate, Intermediate Layer, and Second Substrate
2. Vibration Portion (FIGS. 1 to 3)
   2.1. Overview of Vibration Portion
   2.2. Shape and Dimensions of Vibration Portion
   2.3. Conductors Located on Vibration Portion
      2.3.1. Overview of Conductors Located on Vibration Portion
      2.3.2. Excitation Electrodes
      2.3.3. Pad Electrodes
      2.3.4. Inspection Electrodes
      2.3.5. Multifunctional Electrode
      2.3.6. Material of Conductors Located on Vibration Portion
   2.4. Electrical Connection between Front and Back of Vibration Portion
      2.4.1. Electrical Connection in Through-Holes (FIGS. 5, 6A, and 6B)
      2.4.2. Electrical Connection on Outer Peripheral Surface (FIG. 6C)
3. Frame Portion (FIGS. 1 to 3)
   3.1. Material, Shape, and Dimensions of Frame Portion
   3.2. Conductors Located on Frame Portion
4. First Substrate (FIGS. 1 to 3, 4, and 9)
   4.1. Material, Shape, and Dimensions of First Substrate
   4.2. Conductors Located on First Substrate
5. Second Substrate (FIGS. 1 to 4)
   5.1. Material, Shape, and Dimensions of Second Substrate
   5.2. Conductors Located on Second Substrate
6. Positional Relationship and Other Conditions among Constituents
   6.1. Relationship between First Recess and Vibration Portion (FIGS. 1 to 3, 7, 8A, and 8B)
   6.2. Gap between Vibration Portion and Frame Portion
   6.3. Relationship of Dimensions and Other Conditions among Various Layers
7. Details of Electrical Connection between Vibration Portion and Second Substrate (FIGS. 10 and 11)
   7.1. Grooves in Second Substrate
   7.2. Positional Relationship between First Through-Holes and Second Through-Holes
8. Another Example of Support Structure (FIGS. 18 to 20)
9. Method of Manufacturing Vibrator (FIGS. 12A to 15C)
10. Summary of Embodiment

### 1. Overview of Vibrator

### (1.1. Shape and Dimensions of Vibrator)

The shape of the vibrator 1 (the shape when the first substrate 3, the intermediate layer 7, and the second substrate 5 stacked together) is not particularly limited. In the illustrated example, the shape of the vibrator 1 is approximately a thin (the length in the D3 direction is less than the lengths in other directions) rectangular parallelepiped. The plan-view shape is a rectangle having the longitudinal direction corresponding to the D2 direction. Examples of other shapes of the vibrator 1 include thin shapes having approximately uniform thickness in the D3 direction and plan-view shapes such as circles, ellipses, squares, or polygons (excluding rectangles). Note that in the description of the present disclosure, rectangles do not include squares unless otherwise specified. Similarly, ellipses do not include circles unless otherwise specified.

The specific dimensions of the vibrator 1 are also not particularly limited. An example of the dimensions of a relatively small vibrator 1 is as follows: In plan view, the maximum length in the longitudinal direction (for example, the length of the long sides) and the maximum length in the lateral direction (for example, the length of the short sides) are, for example, 0.5 mm or more and 2 mm or less. The thickness (in the D3 direction) is, for example, 0.1 mm or more and 0.3 mm or less.

### (1.2. Mounting Configuration of Vibrator)

The mounting method of the vibrator 1 onto an external element (for example, a circuit board) is not particularly limited. For example, the mounting method may be surface mounting or through-hole mounting. From a different perspective, the configuration of external electrodes (external terminals) related to the mounting of the vibrator 1 is not particularly limited. For example, the external electrodes of the vibrator 1 may have pad shapes (the illustrated example) used for surface mounting or may have pin shapes used for surface mounting or through-hole mounting.

In the illustrated example, the vibrator 1 includes a first external electrode 15A and a second external electrode 15B (hereinafter also sometimes simply referred to as the “external electrodes 15”) exposed to the outside on the +D3 side. The external electrodes 15 include surfaces facing the +D3 direction and have pad shapes at least in appearance. Although not specifically illustrated, the external electrodes 15, for example, may contribute to mounting as described below.

For example, the −D3 side surface of the vibrator 1 may be joined to a mounting surface of an external element with an adhesive. The external electrodes 15 may be electrically connected, with bonding wires, to pads of the external element or pads of another electronic component mounted on the external element.

Alternatively, the vibrator 1 may be placed with the external electrodes 15 facing pads provided on a mounting surface of an external element. The pads and the external electrodes 15 may be joined by using a conductive joining material (for example, solder) interposed between the pads and the external electrodes 15. Note that in this configuration, the +D3 side surface of the vibrator 1 may be provided with, in addition to the two external electrodes 15, a dummy electrode or an electrode configured to receive a reference potential to stabilize the support of the vibrator 1 by the external element. In particular, when an electrode configured to receive a reference potential is formed to extend over a second recess 39 described later and the frame portion 11 in plan view, the strength of the second substrate 5 can be increased. In addition, when the additional electrode covers most (for example, 70% or more) of the +D3 side surface of the second substrate 5 in the state of being electrically separated from the external electrodes 15, the effects of external electromagnetic waves can be reduced in the vibrator 1. In particular, when the electrode configured to receive a reference potential is connected to a reference potential electrode formed on the −D3 side surface of the first substrate 3 through a side surface of the second substrate 5, a side surface of the intermediate layer 7, and a side surface of the first substrate 3, the effects of external electromagnetic waves can be further reduced.

The positions, shapes, and dimensions of the external electrodes 15 are not particularly limited. For example, unlike the illustrated example, the external electrodes 15 may be located on the −D3 side of the vibrator 1 (from a different perspective, the first substrate 3). The positions of the external electrodes 15 in plan view are also not particularly limited. In the illustrated example, the two external electrodes 15 in plan view are aligned in a direction (a diagonal direction) inclined relative to the longitudinal direction and the lateral direction of the vibrator 1 and relatively distant from the outer edge of the vibrator 1. Unlike the illustrated example, for example, the external electrodes 15 may be located at any ones of the four corners of the vibrator 1 in plan view. In that case, pads may be located outside the vibration portion 9 by using extension lines on the +D3 side of the second substrate 5. Such a configuration reduces transmission of the stress, generated when the vibrator 1 is mounted, to the vibration portion 9. In particular, when the external electrodes 15 are located symmetric with respect to the first recess 14 in plan view, imbalance of the stress generated when the vibrator 1 is mounted can be reduced. In addition, for example, the shapes of the external electrodes 15 may be rectangles (the illustrated example), circles, ellipses, or polygons (excluding rectangles).

### (1.3. Joining of First Substrate, Intermediate Layer, and Second Substrate)

The joining configuration between the first substrate 3 and the intermediate layer 7 and the joining configuration between the intermediate layer 7 and the second substrate 5 are not particularly limited.

In the example illustrated in FIG. 3, the first substrate 3 and the intermediate layer 7 are joined with a first metal layer 17 interposed therebetween. With attention focused on the manufacturing process, a metal layer (a first-substrate-side layer 21, see also FIG. 1) stacked on the first surface 3a of the first substrate 3 and a metal layer (a first-intermediate-side layer 25, see also FIG. 2) stacked on the surface of the intermediate layer 7 facing the first substrate 3 are joined to each other.

In the example illustrated in FIG. 3, the intermediate layer 7 and the second substrate 5 are joined with a second metal layer 19 interposed therebetween. With attention focused on the manufacturing process, a metal layer (a second-substrate-side layer 23, see also FIG. 2) stacked on the second surface 5a of the second substrate 5 and a metal layer (a second-intermediate-side layer 27, see also FIG. 1) stacked on the surface of the intermediate layer 7 facing the second substrate 5 are joined to each other.

Examples of joining configurations other than the illustrated one include a configuration in which the first substrate 3 and the intermediate layer 7 are joined with an insulating layer interposed therebetween and a configuration in which the first substrate 3 and the intermediate layer 7 are directly joined (direct joining). The insulating layer may be composed of an inorganic material (for example, SiO₂) or an organic material (for example, a resin). A metal layer and an insulating layer may be in close contact with each other between the first substrate 3 and the intermediate layer 7. Naturally, these other joining configurations may be applied to the joining of the second substrate 5 and the intermediate layer 7.

The joining configuration between the first substrate 3 and the intermediate layer 7 and the joining configuration between the second substrate 5 and the intermediate layer 7 may differ from each other. For example, a configuration in which the substrate provided with the external electrodes 15 (the second substrate 5 in the illustrated example) and the intermediate layer 7 are joined to each other with a metal layer, and in which the other substrate (the first substrate 3 in the illustrated example) and the intermediate layer 7 are joined to each other with an insulating layer or by direct joining is possible.

The joining configuration between the substrate (3 or 5) and the intermediate layer 7 may differ between different regions in plan view. For example, a configuration in which the vibration portion 9 and the substrate provided with the external electrodes 15 (the second substrate 5 in the illustrated example) are joined to each other with a metal layer, and in which the frame portion 11 and the substrate mentioned above are joined to each other with an insulating layer or by direct joining is possible.

Note that details of the first metal layer 17 and the second metal layer 19 will be described later together with the first substrate 3, the intermediate layer 7, and the second substrate 5.

### 2. Vibration Portion

### (2.1. Overview of Vibration Portion)

The vibration of the vibration portion 9 (the vibration intended to be used, unless otherwise specified) may be of any vibration mode. From a different perspective, the vibration portion 9 and the excitation electrodes 13 may include any configurations.

Examples of vibration modes include thickness shear vibration, thickness extensional vibration, area expansion vibration, length vibration, flexural vibration, torsional vibration, and contour shear vibration. The vibration mode may be one that generates acoustic waves (for example, surface acoustic wave (SAW)). As can be understood from the example of SAW, the vibration mode is not limited to ones in which the entire part of the vibration portion 9 in the thickness direction vibrates but may be one in which part of the vibration portion 9 in the thickness direction vibrates.

As can be understood from the examples of the vibration modes mentioned above, for example, the vibration portion 9 may be integrally formed by using a piezoelectric material for the entire vibration portion 9 (the illustrated example), or only part of the vibration portion 9 may be composed of a piezoelectric material. Examples of the latter include a configuration in which the vibration portion 9 includes a piezoelectric material layer that propagates acoustic waves and another layer stacked on this piezoelectric material layer.

The specific material of the piezoelectric material may be of any kind depending on the used vibration mode. For example, the piezoelectric material may be a single crystal or a polycrystal. Examples of the former include quartz crystal, single-crystal lithium tantalate, and single-crystal lithium niobate. Examples of the latter include various types of ceramic.

The cut angle of a single crystal is not particularly limited. Examples of cut angles for quartz crystal include AT-cut, SC-cut, and BT-cut used for thickness shear vibration, and CT-cut and DT-cut used for contour shear vibration.

For example, as can be understood from the examples of the vibration modes mentioned above, the paired excitation electrodes 13 may face each other with the vibration portion 9 in between in the thickness direction or another direction (the illustrated example), or paired excitation electrodes 13 may be located on the same one surface (plane) of the vibration portion 9. Examples of the latter include paired comb shaped electrodes for exciting acoustic waves.

In the description of the embodiment, an AT-cut quartz crystal piece used for thickness shear vibration is taken as an example of the vibration portion 9 for convenience. To be sure, thickness shear vibration is a vibration mode in which two surfaces opposed to each other in thickness direction (the D3 direction) vibrate so as to slide relative to each other. As for a quartz crystal piece with a cut angle of AT-cut, when the axes obtained by rotating the Z-axis (the optical axis) and the Y-axis (the mechanical axis) by 35° or more and 36° or less (for example, 35° 15′) around the X-axis (the electric axis) are defined as the Z′-axis and the Y′-axis, the thickness direction of the AT-cut quartz crystal piece is aligned with the Y′ axis (from a different perspective, the front and back surfaces are parallel to the X-axis and the Z′-axis).

The relationship between the vibration direction (from a different perspective, the orientation of crystal) and the configuration of the vibrator 1 (the vibration portion 9) is not particularly limited. For example, the direction of thickness shear vibration (the X-axis direction) may be the D1 direction, the D2 direction, or a direction inclined relative to these directions. However, the description of the embodiment is sometimes based on an example of a configuration in which the D2 direction is the direction of thickness shear vibration without any notification for convenience.

### (2.2. Shape and Dimensions of Vibration Portion)

The shape of the vibration portion 9 is not particularly limited. For example, the vibration portion 9 may have a plate shape with an approximately uniform thickness throughout its entire part (the illustrated example), or may be of a so-called mesa type or inverted-mesa type. In this description, the term “a plate shape and/or a uniform thickness” denotes, for example, that the difference between the average thickness of the overlapping region described later where the vibration portion 9 and the outer periphery (the outer peripheral region 3b) of the first recess 14 overlap each other (or the joint region where the two members are joined) and the average thickness of the excitation portion 9a is within +5% of the average thickness of the excitation portion 9a, and/or that the difference between the minimum thickness and the maximum thickness of the vibration portion 9 is within +5% of the average thickness of the excitation portion 9a. A mesa type is, for example, a shape in which the region (the mesa portion) that approximately matches the arrangement region of the excitation electrodes 13 is thicker than the surrounding area. Specifically, for example, the difference between the average thickness of the mesa portion and the average thickness of the surrounding area may be greater than 5% and/or less than or equal to 40%. An inverted mesa type is, for example, a shape in which the region (the inverted mesa portion) including the arrangement region of the excitation electrodes 13 is thinner than the surrounding area. The specific shapes (the planar shape, the inclination of the side surface, the number of steps of height change, and the like) of the mesa portion and the inverted mesa portion are also not particularly limited.

The planar shape of the vibration portion 9 is also not particularly limited. For example, the planar shape of the vibration portion 9 may be a rectangle (for example, a rectangle or a square) (the illustrated example), a circle, an ellipse, or a polygon (excluding rectangles). From a different perspective, the vibration portion 9 may have a shape having the longitudinal direction and the lateral direction (for example, a rectangle or an ellipse) or a shape without such a distinction (for example, a circle or a square). The ratio between the length in the longitudinal direction and the length in the lateral direction is also not particularly limited. For example, the ratio between the former and the latter may range from 1.14:1 to 1.39:1, or may be 1.26:1.

The relationship between the shape of the vibration portion 9 and the orientation of crystal (the direction of vibration) is not particularly limited. For example, in a configuration in which the vibration portion 9 has the longitudinal direction and the lateral direction in plan view, the direction of thickness shear vibration (in the X-axis direction) may correspond to the longitudinal direction, the lateral direction, or a direction inclined relative to the longitudinal direction. The ratio between the length in the longitudinal direction and the length in the lateral direction in the previous paragraph may be applied to a configuration in which the direction of thickness shear vibration is aligned with the longitudinal direction.

The dimensions of the vibration portion 9 are not particularly limited. However, the dimensions that affect the resonance frequency of the vibration portion 9 are set according to the frequency intended to be used. The dimensions that affect the resonance frequency differ depending on the vibration mode. For example, in the case of thickness shear vibration, the thickness of the vibration portion 9 (more specifically, the excitation portion 9a) determines the resonance frequency. When the n-th order wave is used in an AT-cut vibration portion 9, it is known that the resonance frequency f0 (MHz) is approximated by f0=1.67×n/t, where t (mm) represents the thickness of the excitation portion 9a.

As described later, vibrators 1 can be packaged in a wafer state with the three layers (3, 5, and 7) stacked together. In other words, the vibrator 1 may be of a WLP type. In this case, a process for adjusting the thickness of the vibration portion 9 can be performed in a wafer state. With this process, for example, the vibration portion 9 can be processed so as to be extremely thin by plasma chemical vaporization machining (CVM) capable of highly accurate machining (for example, +5 nm).

As can be understood from the previous paragraph, the vibration portion 9 may be relatively thin. For example, the vibration portion 9 may have a thickness of 5 μm or more and 10 μm or less, or 5 μm or more and 6 μm or less. When thickness shear vibration is used, the thinner the vibration portion 9, the higher the resonance frequency. Hence, from a different perspective, use of the vibration portion 9 at a relatively high frequency may be intended. For example, when the dimensions mentioned above are applied to the aforementioned expression for the resonance frequency of AT-cut, the result is approximately 167 MHz or more and 334 MHz or less, or 278 MHz or more and 334 MHz or less.

### (2.3. Conductors Located on Vibration Portion)

### (2.3.1. Overview of Conductors Located on Vibration Portion)

The vibration portion 9 includes, for example, the following conductor layers (metal layers): the paired excitation electrodes 13 already mentioned; paired pad electrodes 29 (a first pad electrode 29A and a second pad electrode 29B), paired inspection electrodes 31 (a first inspection electrode 31A and a second inspection electrode 31B), and two wiring portions 35, located on the +D3 side of the vibration portion 9; and the multifunctional electrode 33 including the second excitation electrode 13B, located on the −D3 side of the vibration portion 9.

The paired pad electrodes 29 contributes to, for example, the connection between the paired excitation electrodes 13 and the paired external electrodes 15. The paired inspection electrodes 31 contributes to, for example, connecting an inspection device for inspecting the characteristics of the vibration portion 9 to the paired excitation electrodes 13 in a manufacturing process. As for the multifunctional electrode 33, for example, part of it functions as the second excitation electrode 13B, and another part of it contributes to the electrical connection between the second excitation electrode 13B and a conductor on the +D3 side of the vibration portion 9 and joining the vibration portion 9 to the first substrate 3.

The various conductors (13A, 29, 31, and 35) located on the +D3 side of the vibration portion 9 are included in the aforementioned second-intermediate-side layer 27. The multifunctional electrode 33 located on the −D3 side is included the aforementioned first-intermediate-side layer 25.

### (2.3.2. Excitation Electrodes)

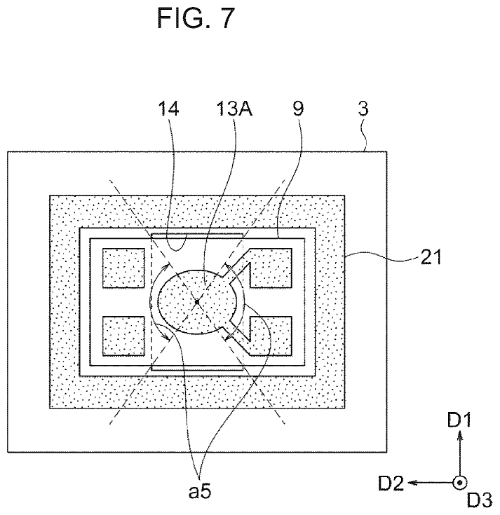

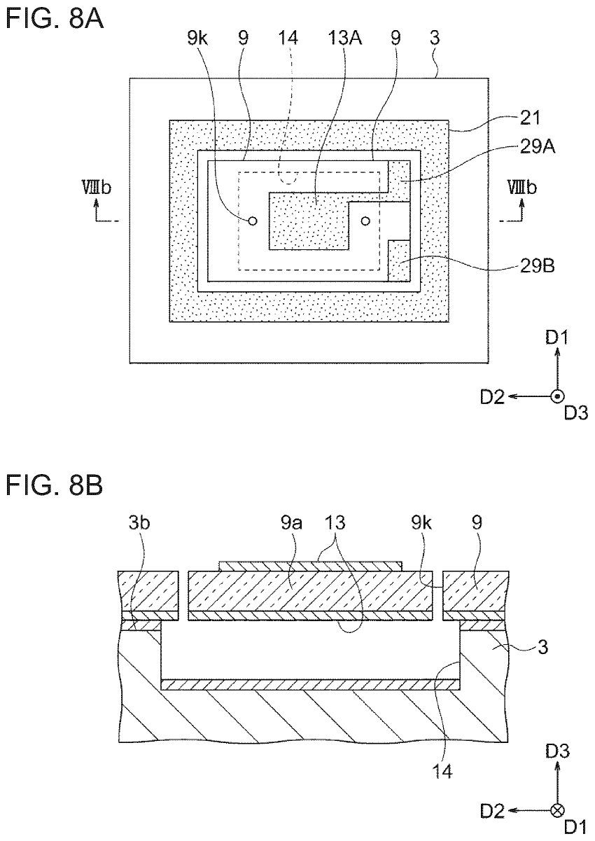

The shape and dimensions of the first excitation electrode 13A (and those of the second excitation electrode 13B) are not particularly limited. For example, the shape of the first excitation electrode 13A may be a circle (the example in FIG. 1), an ellipse (see FIG. 7), a rectangle (for example, a rectangle or a square, see FIG. 8A), or a polygon (excluding rectangles). From a different perspective, the first excitation electrode 13A may have a shape having the longitudinal direction and the lateral direction (for example, a rectangle or an ellipse) or a shape without such a distinction (for example, a circle or a square). The ratio between the length in the longitudinal direction and the length in the lateral direction is also not particularly limited. For example, the ratio between the former and the latter may range from 1.14:1 to 1.39:1, or may be 1.26:1.

The relationship between the shape of the first excitation electrode 13A and the orientation of crystal (the direction of vibration) is not particularly limited. Typically, in a configuration in which the first excitation electrode 13A has the longitudinal direction and the lateral direction, the direction of thickness shear vibration (the X-axis direction) corresponds to the longitudinal direction. The ratio between the length in the longitudinal direction and the length in the lateral direction in the previous paragraph may be applied to this configuration.

The positional relationship between the first excitation electrode 13A and the vibration portion 9 is also not particularly limited. For example, the geometric center of the first excitation electrode 13A and the geometric center of the vibration portion 9 may be aligned with each other (the illustrated example) or may be deviated from each other. In a configuration in which each of the first excitation electrode 13A and the vibration portion 9 has the longitudinal direction and the lateral direction, the longitudinal direction of the first excitation electrode 13A may be aligned with the longitudinal direction of the vibration portion 9 (the example in FIGS. 7 and 8A), but this is not essential. In a configuration in which the vibration portion 9 includes a mesa portion or an inverted mesa portion, the positional relationship (whether the shapes and/or the sizes are the same or different, which is larger when the sizes are different, and other conditions) between the first excitation electrode 13A and the mesa or inverted mesa portion is also not particularly limited.

### (2.3.3. Pad Electrodes)

Each one of the paired pad electrodes 29 is electrically connected to the corresponding one of the paired excitation electrodes 13. Both of the paired pad electrodes 29 face the second substrate 5 (the +D3 direction) and thus can be joined to conductors on the second substrate 5 (for example, the second-substrate-side layer 23). With this configuration, each one of the paired excitation electrodes 13 is electrically connected to the corresponding one of the paired external electrodes 15 of the second substrate 5.

The first pad electrode 29A is connected to the first excitation electrode 13A. Specifically, since the two electrodes are located on the +D3 side of the vibration portion 9, they are connected to each other by a wiring portion 35 located on the +D3 side of the vibration portion 9.

The second pad electrode 29B is connected to the second excitation electrode 13B. Specifically, the two electrodes are connected to each other through the region (an outer electrode 33a) of the multifunctional electrode 33 other than the second excitation electrode 13B. The configuration of the electrical connection between the outer electrode 33a and the second pad electrode 29B (the electrical connection between the front and back of the vibration portion 9) will be described later (in Section 2.4).

The shapes and positions of the paired pad electrodes 29 are not particularly limited. For example, the shapes of the pad electrodes 29 may be rectangles (the illustrated example) or circles. The pad electrodes 29 may be away from the outer edge of the vibration portion 9 (the example in FIG. 1) or may extend to an outer edge of the vibration portion 9 (see FIG. 8A). The shapes, dimensions, and positions of the paired pad electrodes 29 may be rotationally-symmetric with respect to the center of the vibration portion 9 (the example in FIG. 1) or line-symmetric with respect to the center line of the vibration portion 9 parallel to the D1 direction or the D2 direction (see FIG. 8A), or a configuration without such relationship is also possible.

In addition, for example, the paired pad electrodes 29 may be located on both sides of the paired excitation electrodes 13 in a specified direction (the example in FIG. 1) or may be located on one side in a specified direction (see FIG. 8A). From a different perspective, the arrangement direction of the paired pad electrodes 29 is not particularly limited. The specified direction mentioned above is not particularly limited. In the example in FIG. 1, the specified direction mentioned above may be regarded as approximately the vibration direction and/or the longitudinal direction of the vibration portion 9 or more specifically may be regarded as a direction (diagonal direction) intersecting the vibration direction and/or the longitudinal direction of the vibration portion 9. The specified direction mentioned above is not limited to the longitudinal direction and may be the lateral direction.

In general, at the positions of the paired pad electrodes 29, the vibration of the vibration portion 9 is restricted, and hence, the probability of affecting the vibration characteristics is high. However, in the present embodiment, the vibration portion 9 is, for example, fixed to the first substrate 3 approximately across its entire surface outside the first recess 14. Hence, the positions of the paired pad electrodes 29 have relatively low effects on the vibration. From a different perspective, the degree of freedom in designing the paired pad electrodes 29 is high in terms of the relationship with the vibration characteristics.

### (2.3.4. Inspection Electrodes)

Each of the paired inspection electrodes 31 is electrically connected to the corresponding one of the paired excitation electrodes 13. Both of the paired inspection electrodes 31 face the +D3 direction. Hence, for example, before the second substrate 5 is joined to the intermediate layer 7, a probe can be brought into contact with the paired inspection electrodes 31 to apply a voltage to the paired excitation electrodes 13. This enables inspection of the characteristics of the vibration portion 9.

The first inspection electrode 31A is connected to the first excitation electrode 13A. Specifically, since the two electrodes are located on the +D3 side of the vibration portion 9, they are connected to each other by a wiring portion 35 located on the +D3 side of the vibration portion 9.

The second inspection electrode 31B is connected to the second excitation electrode 13B. Specifically, the two electrodes are connected to each other through the region (the outer electrode 33a) of the multifunctional electrode 33 other than the second excitation electrode 13B.

The shapes and positions of the inspection electrodes 31 are not particularly limited. The explanation of the shapes and positions of the pad electrodes 29 described above may be applied to the shapes and positions of the inspection electrodes 31. The shapes, dimensions, and positions of the inspection electrodes 31 may be line-symmetric with the shapes, dimensions, and positions of the pad electrodes 29 with respect to the center line of the vibration portion 9 parallel to the D1 direction or the D2 direction (the example in FIG. 1), or may be rotationally symmetric with respect to the center of the vibration portion 9, or a configuration without such relationship is also possible.

Note that a configuration without the paired inspection electrodes 31 is also possible (see FIG. 8A). In this case, inspection can also be performed by bringing a probe into contact with the pad electrodes 29. For example, unlike the pad electrodes 29, the inspection electrodes 31 are not joined to conductors on the second substrate 5. However, they may be joined to conductors on the second substrate 5.

### (2.3.5. Multifunctional Electrode)

The multifunctional electrode 33, for example, extends over approximately the entire-D3 side surface of the vibration portion 9. From a different perspective, the multifunctional electrode 33 has a so-called solid pattern. A solid pattern refers to, for example, a pattern extending over a relatively large area basically without a gap. With this configuration, the multifunctional electrode 33 not only includes the second excitation electrode 13B but also includes the outer electrode 33a that contributes to electrical connection and joining. Specifically, the outer electrode 33a contributes to the electrical connection between the second excitation electrode 13B and conductors on the +D3 side of the vibration portion 9 (the second pad electrode 29B and the second inspection electrode 31B) and also contributes to the joining of the vibration portion 9 and the first substrate 3.

However, the multifunctional electrode 33 is not limited to a solid pattern extending over the entire −D3 side surface of the vibration portion 9.

For example, the multifunctional electrode 33 may have a solid pattern with outer edges that are partially or entirely away from the outer edge of the vibration portion 9. The solid pattern in this case, for example, may include a region overlapping approximately the entire excitation electrodes 13 and a region overlapping part of the outer peripheral region 3b surrounding the first recess 14 and occupy 80% or more of the area of the vibration portion 9.

For example, the multifunctional electrode 33 may include the second excitation electrode 13B, an outer electrode (33a) surrounding the second excitation electrode 13B and away from the outer edge of the second excitation electrode 13B, and a wiring portion connecting the two electrodes. From a different perspective, an annular slit (part of which is interrupted by the wiring portion) may be formed between the second excitation electrode 13B and the outer electrode 33a. In this configuration, for example, the second excitation electrode 13B may have a shape approximately the same as the shape of the first excitation electrode 13A in perspective plan view.

For example, the multifunctional electrode 33 may include a portion contributing to the electrical connection between the second excitation electrode 13B and the second pad electrode 29B (and/or the second inspection electrode 31B) and a portion contributing to the joining of the vibration portion 9 and the first substrate 3, and these portions may be electrically separated from each other. In this case, the latter may be electrically floated or may receive a reference potential.

### (2.3.6. Material of Conductors Located on Vibration Portion)

The multifunctional electrode 33 on the −D3 side of the vibration portion 9 is included in the first-intermediate-side layer 25 mentioned earlier. The various conductor layers (13A, 29, 31 and 35) on the +D3 side of the vibration portion 9 are included in the second-intermediate-side layer 27. Hence, in the description in this section, the terms “first-intermediate-side layer 25” and “second-intermediate-side layer 27” may be sometimes used for explanation for convenience.

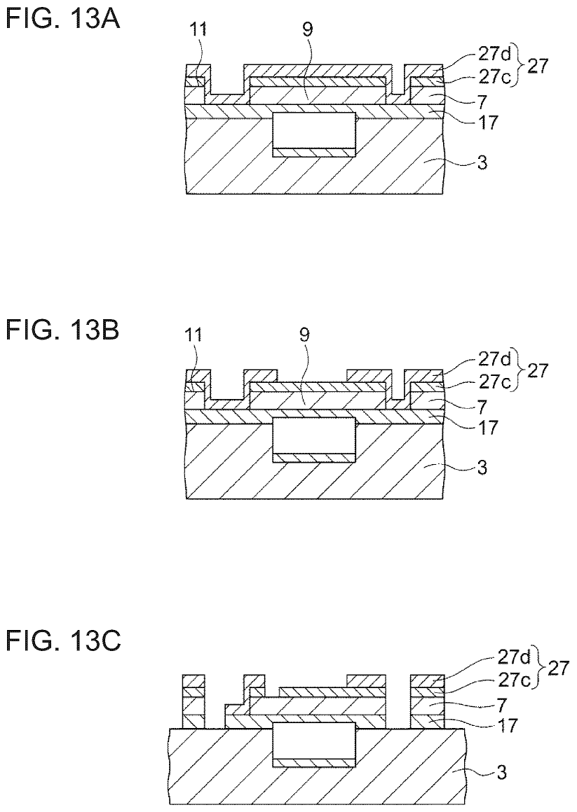

The various conductor layers (13A, 29, 31, and 35) located on the +D3 side of the vibration portion 9 may be composed of the same material and have the same thickness (the example in FIG. 3) or may be composed of different materials and/or have different thicknesses (see FIG. 13C). Examples of the latter configuration include one in which the pad electrodes 29 (and the inspection electrodes 31) include a metal layer the same as one composing the first excitation electrode 13A and additionally include another metal layer, which is not included in the first excitation electrode 13A, on the foregoing metal layer.

Similarly, the multifunctional electrode 33 located on the −D3 side of the vibration portion 9 may be composed of the same material and have the same thickness throughout its entire area (the example in FIG. 3) or may be composed of different materials and/or have different thicknesses depending on the regions. Examples of the latter configuration include one in which the second excitation electrode 13B and the outer electrode 33a are composed of different materials and/or have different thicknesses, as in the +D3 side.

In a configuration in which the conductor layers are composed of the same material and have the same thickness throughout the entire area on each of the +D3 side and the −D3 side, the conductor layers (13A, 29, 31, and 35) on the +D3 side and the conductor layer (33) on the −D3 side may be composed of the same material and have the same thickness (the example in FIG. 3) or may be composed of different materials and/or have different thicknesses. Also in a configuration in which the conductor layers are not composed of the same material and do not have the same thickness throughout the entire area on at least one of the +D3 side or the −D3 side, the materials and/or the thicknesses may be the same or different when they are compared between specific regions (for example, between the excitation electrodes 13 or between other regions).

Note that, for example, the thickness of an excitation electrode 13 (for example, the first excitation electrode 13A) is sometimes fine-tuned after joining to the first substrate 3 to adjust the frequency. When determining whether the thickness is the same or not, the effects from such fine-tuning are ignored. In addition, for example, the effects from pressing and heating when the three layers (3, 5, and 7) are joined are also ignored. The same and/or similar explanation applies to the conductor layers on the first substrate 3 and the second substrate 5.

The material of the first-intermediate-side layer 25 and the second-intermediate-side layer 27 is not particularly limited. For example, each layer (25 or 27) may be composed of a single metal layer or two or more metal layers (the example in FIG. 3). Note that when it is stated that a specific layer (for example, 25 or 27) is composed of two or more metal layers (or insulating layers) and that the same material is used throughout a specific region, the number of stacked metal layers and the material of each metal layer (in addition, the ratios of thicknesses of the metal layers), for example, are the same. The same and/or similar explanation applies to other layers.

In the example in FIG. 3, the first-intermediate-side layer 25 includes a lower layer 25a in contact with (directly stacked on) the vibration portion 9 and an upper layer 25b stacked on the lower layer 25a. For example, the upper layer 25b is composed of a material having a higher conductivity than the material of the lower layer 25a and is thicker than the lower layer 25a. The lower layer 25a, for example, contributes to improving the joint strength between the upper layer 25b and the vibration portion 9. However, the layered structure may be intended to have a different function from the one mentioned above.

Specific materials of the lower layer 25a and the upper layer 25b are not particularly limited. Examples of the material of the lower layer 25a include chromium (Cr), titanium (Ti), nickel (Ni), and alloys containing one or more of these as a main component. Examples of the material of the upper layer 25b include gold (Au), silver (Ag), platinum (Pt), aluminum (Al), and alloys containing one or more of these as a main component.

In the example in FIG. 3, the second-intermediate-side layer 27 includes a lower layer 27a, an upper layer 27b, a first joint layer 27e, and a second joint layer 27f in this order from the vibration portion 9. The first excitation electrode 13A and the wiring portions 35 are composed of, for example, the lower layer 27a and the upper layer 27b of the four layers mentioned above. The pad electrodes 29, the inspection electrodes 31, and the portion overlapping the frame portion 11 of the second-intermediate-side layer 27 are composed of, for example, the four layers mentioned above.

The previous description of the material of the first-intermediate-side layer 25 may be applied to the second-intermediate-side layer 27 within a range that makes no contradiction or the like by replacing the terms “first-intermediate-side layer 25”, “lower layer 25a”, and “upper layer 25b” with the terms “second-intermediate-side layer 27”, “lower layer 27a”, and “upper layer 27b”, respectively. In addition, the previous description of the material of the first-intermediate-side layer 25 may be applied to the second-intermediate-side layer 27 within a range that makes no contradiction or the like by replacing the terms “first-intermediate-side layer 25”, “lower layer 25a”, and “upper layer 25b” with the terms “second-intermediate-side layer 27”, “first joint layer 27e”, and “second joint layer 27f”, respectively.

### (2.4. Electrical Connection Between Front and Back of Vibration Portion)

### (2.4.1. Electrical Connection in Through-Holes)

FIG. 5 is a perspective view of the vibration portion 9. This figure illustrates the conductors on the +D3 side of the vibration portion 9 with the dotted lines. FIG. 6A is a cross-sectional view taken along line VIa-VIa in FIG. 5. FIG. 6B is a cross-sectional view taken along line VIb-VIb in FIG. 5.

As illustrated in these figures, the vibration portion 9 includes first through-holes 9h. Connection conductors 37 located in these first through-holes 9h electrically connect conductor layers on the +D3 side of the vibration portion 9 and conductor layers on the −D3 side of the vibration portion 9.

The configuration of the connection conductor 37 is not particularly limited. For example, the connection conductor 37 may be a pillar-shaped conductor with which the first through-hole 9h is filled (the illustrated example) or may be a layered conductor stacked on the inner surface the first through-hole 9h. The entire pillar-shaped conductor may be composed of a single material or may be composed of two or more materials. Example of the latter configuration include one in which the outer peripheral surface and the inner portion are composed of different materials (the example in FIG. 3). Similarly, as for the layered conductor, the entire part may be composed of a single material or two or more materials. Examples of the latter configuration include one including a layer in contact with the inner surface of the first through-hole 9h and another layer stacked on this layer. The material of the connection conductor 37 may be the same as or different from the material of the conductor layers on the +D3 side and/or the −D3 side.

Note that the explanation in the previous paragraph may be applied to second through-holes 5h described later and extension conductors 41 located inside the second through-holes 5h. In this case, the terms “first through-hole 9h” and “connection conductor 37” are replaced with the terms “second through-hole 5h” and “extension conductor 41”, respectively.

FIG. 3 illustrates, as an example, the connection conductor 37 including a configuration including an outer peripheral side layer composed of the same material as the first joint layer 27e and a pillar-shaped portion located inside and composed of the same material as the second joint layer 27f. Note that as in the description above, FIG. 3 illustrates, as an example, the extension conductors 41 described later, composed of the same materials as the two or more conductor layers stacked on the +D3 side surface of the second substrate 5.

Returning to FIG. 5, the positions, shapes, and dimensions of the first through-holes 9h (from a different perspective, the connection conductors 37) are not particularly limited. For example, in the illustrated example, with attention focused on the first through-hole 9h that contributes to the electrical connection between the second pad electrode 29B and the multifunctional electrode 33, the first through-hole 9h is located immediately below the second pad electrode 29B, and more specifically, for example, located closer to the excitation electrode 13 than the geometric center of the second pad electrode 29B (even more specifically, for example, located closer the excitation electrode 13 than the geometric center of the second pad electrode 29B in the longitudinal direction and/or the vibration direction of the vibration portion 9). In the illustrated example, the foregoing first through-hole 9h associated with the second pad electrode 29B has a slit shape extending in a direction intersecting (for example, orthogonal to) the arrangement direction of the second pad electrode 29B and the excitation electrode 13 (from a different perspective, the longitudinal direction and/or the vibration direction of the vibration portion 9).

The first through-hole 9h located immediately below the second pad electrode 29B, for example, simplifies the pattern of the conductor layers on the +D3 side, making it easier to reduce the area of the conductor layers. The first through-hole 9h located closer to the excitation electrode 13, for example, enables the first through-hole 9h to provides a function of blocking the transmission of stress between the pad electrode 29 and the excitation portion 9a, reducing the effects of the fixation of the pad electrode 29 to the second substrate 5 on the vibration of the excitation portion 9a. This benefit is improved by the first through-hole 9h having a slit shape extending in a direction intersecting the arrangement direction of the second pad electrode 29B and the excitation electrode 13. The first through-hole 9h having a slit shape makes it easy to achieve a sufficient length of the inner peripheral surfaces of the first through-hole 9h in plan view, making it easy to achieve a sufficient area for the electrical connection between the connection conductor 37 in the first through-hole 9h and the conductor layers on the +D3 side and the −D3 side.

However, the positions, shapes, and dimensions of the first through-holes 9h may be different from those mentioned above. Such examples are as follows: For example, the first through-hole 9h need not be located immediately below the second pad electrode 29B. In this case, the connection conductor 37 and the second pad electrode 29B may be connected, for example, by a wiring portion located on the +D3 side. The first through-hole 9h may be located at the geometric center of the second pad electrode 29B or on the opposite side of the geometric center from the excitation electrode 13, in the arrangement direction of the second pad electrode 29B and the excitation electrode 13 (from a different perspective, the longitudinal direction and/or the vibration direction of the vibration portion 9). The shape of the first through-hole 9h in plan view may also be a circle, an ellipse (that is hardly regarded as a slit shape), a square, or a rectangle (that is hardly regarded as a slit shape).

Although the first through-hole 9h associated with the second pad electrode 29B has been described, the aforementioned explanation of the position, shape, and dimensions of the first through-hole 9h may be applied as appropriate to the first through-hole 9h associated with the second inspection electrode 31B.

The shape and dimensions of the vertical section of the first through-hole 9h (the sections illustrated in FIGS. 6A and 6B) are not particularly limited. These figures illustrate, as an example, a tapered shape the width of which decreases toward the −D3 side. Unlike the illustrated example, the vertical section of the first through-hole 9h may have, for example, a shape having a uniform width; a shape in which the closer to the center in the thickness direction of the vibration portion 9, the smaller the width (a shape having two tapered shapes); or a shape including multiple steps. The tapered shape may be formed due to the anisotropy of the material of the vibration portion 9 in etching or intentionally formed by adjusting the irradiation mode of laser light or other methods.

A supplementary explanation regarding the slit shape of the first through-hole 9h will be provided. A slit shape can be defined as a shape in which the length in a first direction (the D1 direction) is longer than the length in a second direction (the D2 direction) orthogonal to the first direction. A slit shape, for example, may extend basically with a uniform width (excluding the end portions). The ratio between the length (in the first direction) and the width (in the second direction) of the slit may be set as appropriate. For example, the length may be greater than or equal to twice, three times, or five times the width, for example.

When the vertical section of the first through-hole 9h having a slit shape is in a tapered shape, θ1 is defined as the taper angle (the angle formed by the two inner surfaces) of the tapered shape in the vertical section orthogonal to the longitudinal direction (the D1 direction). θ2 is defined as the taper angle of the tapered shape in the vertical section orthogonal to the lateral direction (the D2 direction). In this case, θ1 may be larger than θ2. From a different perspective, when the inclination angle of the inner surfaces of the first through-hole 9h relative to the +D3 side surface of the vibration portion 9 is defined as the average of the inclination angles of the two inner surfaces, the inclination angle of the vertical cross section orthogonal to the longitudinal direction (the D1 direction) may be smaller than the inclination angle of the vertical cross section orthogonal to the lateral direction. This is expressed by the following expression.

$$( 180 ° - θ1 ) / 2 < ( 180 ° - θ2 ) / 2$$

The function of such a configuration will be mentioned later in the summary of the embodiment (in Section 10).

As will be mentioned later in Section 9, the first through-holes 9h may be formed by single-sided etching of the vibration portion 9 from the +D3 side. In this case, tapered shapes are formed due to the anisotropy of the material of the vibration portion 9 in etching. For example, when the vibration portion 9 is composed of a single crystal, crystal surfaces appear by etching and form the inner surfaces of the first through-hole 9h. The angles of the crystal surfaces relative to the +D3 side surface are determined by the crystal structure. As etching progresses, new different crystal surfaces sometimes appear and coexist with or replace the crystal surfaces that appeared previously. When a tapered shape is formed due to crystal surfaces as described above, to form a configuration as in the previous paragraph, the orientation of the slit is set as appropriate to be adapted to the orientation of the crystal.

For example, in the case of AT-cut, the D1 direction, the D2 direction, and the D3 direction correspond to the Z′-axis direction, the X-axis direction, and the Y′ axis direction, respectively, as mentioned above. In this case, the longitudinal direction of the slit may be set to the D1 direction (the Z′-axis direction) as in the illustrated example. As for the taper angles θ1 and θ2 in this case, for example, θ1=approximately 82° and θ2=approximately 57°, or θ1=approximately 113° and θ2=approximately 72° (or approximately) 91° although these depend on the progress of etching. From a different perspective, θ1 may be larger than θ2 by a difference of 20° or more. Note that when the crystal surfaces do not clearly appear at the end portions (the short sides) of the slit, whether the taper angle of the inner surfaces corresponding to the long sides of the slit is set to be relatively larger may be judged according to the crystal surfaces of the side surfaces of the vibration portion 9.

### (2.4.2. Electrical Connection on Outer Peripheral Surface)

FIG. 6C is a cross-sectional view of another example of the electrical connection between the front and back of the vibration portion 9, and this figure corresponds to FIG. 6A. Note that the vibration portion 9 according to this configuration of electrical connection is sometimes referred to as the term “vibration portion 9A” for convenience. In this figure, illustration of the first inspection electrode 31A is omitted (or the vibration portion 9A actually does not include the first inspection electrode 31A).

As for the vibration portion 9A, the electrical connection between the front and back of the vibration portion 9 is achieved by a connection layer 38 which is a layer stacked on an outer peripheral surface (a side surface) of the vibration portion 9A. Note that unlike the illustrated example, both the electrical connection by the first through-holes 9h and the electrical connection by a side surface of the vibration portion 9 may be used in parallel.

Specifically, the connection layer 38 includes a region extending from an edge portion on the +D3 side to an edge portion on the −D3 side in part of the outer peripheral surface of the vibration portion 9A in plan view, and this region connects the second pad electrode 29B and the multifunctional electrode 33. The connection layer 38 may include only the region located on the outer peripheral surface of the vibration portion 9A or may include, in addition to this region, a region located on the +D3 side of the vibration portion 9A and/or a region located on the −D3 side of the vibration portion 9A.

Although not specifically illustrated, another connection layer 38 is provided for connecting the second inspection electrode 31B and the multifunctional electrode 33. Note that although the following only describes the connection layer 38 connecting the second pad electrode 29B and the multifunctional electrode 33, this description may be applied to the connection layer 38 connecting the second inspection electrode 31B and the multifunctional electrode 33 as appropriate.

The position, shape, and dimensions of the connection layer 38 are not particularly limited. For example, the connection layer 38 may be located on any one or more side surfaces out of the outer peripheral surfaces on the −D2 side, on the +D2 side, on the +D1 side, and on the −D1 side. From a different perspective, the relationship between the side surface where the connection layer 38 is located and the longitudinal direction and/or the vibration direction of the vibration portion 9A is not particularly limited. In the example in FIG. 6C, the connection layer 38 includes a region located on the side surface on the +D2 side. It can be said that the side surface on the +D2 side is the side surface on one end side (an end surface) in the longitudinal direction and/or the vibration direction of the vibration portion 9A and/or the side surface on the side closer to the second pad electrode 29B (and the second inspection electrode 31B) than the excitation electrode 13. The connection layer 38 may include, in addition to or instead of the region on the side surface on the +D2 side, a region located on the side surface on the +D1 side (the side where the second pad electrode 29B is located in the lateral direction of the vibration portion 9A).

For example, the range in the D1 direction where the region of the connection layer 38 is located on the side surface on the +D2 side may match the range in the D1 direction of the second pad electrode 29B, the former may be part of the latter, the latter may be part of the former, or the former and the latter may be shifted from each other. From a different perspective, for example, the connection layer 38 may have such a shape that the second pad electrode 29B is extended in the +D2 direction or may have a shape extending from the second pad electrode 29B, similarly to the wiring portion 35. Although the above description is based on an example of the side surface on the +D2 side, the same and/or similar configuration may be applied to the side surface on the +D1 side.

The material and thickness of the connection layer 38 are not particularly limited. For example, the material and/or thickness of the connection layer 38 may be the same as or different from the material and/or thickness of part or all of the region in plan view of the conductor layer on the +D3 side (and/or the −D3 side) of the vibration portion 9.

A supplementary explanation will be provided for the side surface of the vibration portion 9 where the connection layer 38 is located. The side surface where the connection layer 38 is located may be, for example, an inclined surface inclined outward of the vibration portion 9 as it extends in the −D3 direction (toward the first substrate 3). This, for example, improves the reliability of the connection between the conductor layers at the ridge line of the +D2 side surface and the +D3 side surface. as the inner peripheral surfaces of the first through-hole 9h, the inclination of the side surface of the vibration portion 9 mentioned above may be formed due to the anisotropy of the material of the vibration portion 9 in etching or intentionally formed by adjusting the irradiation mode of laser light or other methods.

Assuming that the connection layer 38 includes a region located on the side surface on one side (the +D2 side) in a specified direction (for example, the longitudinal direction and/or the vibration direction of the vibration portion 9A) and does not include a region located on the side surface on the other side (the −D2 side) in the specified direction. In this case, for example, the inclination angle θ3 of the side surface on the +D2 side relative to the normal line of the +D3 side surface of the vibration portion 9 may be larger than the inclination angle θ4 of the side surface on the −D2 side relative to the normal line mentioned above. In this case, the benefit mentioned in the previous paragraph is higher than in a configuration in which the relationship between angles θ3 and θ4 is opposite to the relationship mentioned above (this configuration is also included in the techniques according to the present disclosure).

In a configuration in which the inclined side surface of the vibration portion 9 is a crystal surface exposed by etching, the orientation of each constituent of the vibration portion 9A (in other words, the orientation of the Cartesian coordinate system D1D2D3) may be set so that the relationship of the angles as mentioned above holds depending on the orientation of the crystal. For example, in a configuration in which the outer peripheral surfaces of the vibration portion 9A of AT-cut are formed by single-sided etching from the +D3 side (in the Y′ axis direction), the +D2 side (the direction of the side surface where the connection layer 38 is located) may be set to the −Z′ side. In this case, for example, θ3 is approximately 56°, and θ4 is approximately 32° although these depend on the progress of etching. From a different perspective, θ3 may be larger than θ4 by a difference of 15° or more. Note that the first through-hole 9h need not be composed of surfaces extending with uniform inclination relative to the D3 direction. Specifically, the first through-hole 9h may include a first tapered portion the opening of which gradually narrows as it extends from the surface facing the first substrate 3 toward the second substrate 5 and a second tapered portion the opening of which gradually narrows as it extends from the surface facing the second substrate 5 toward the first substrate 3.

Note that in the description of the shape and dimensions of the vibration portion 9 and the like, the effects of the inclination of the side surfaces as mentioned above is basically ignored. Hence, for example, shapes and dimensions in plan view may be, for example, applied to each of the +D3 side surface and the −D3 side surface or may be applied to the maximum shape or the maximum dimension in plan view of both side surfaces.

### 3. Frame Portion

### (3.1. Material, Shape, and Dimensions of Frame Portion)

As described above, the frame portion 11 surrounds the vibration portion 9 in plan view and is away from the entire periphery of the outer edge of the vibration portion 9. The material, shape, and dimensions of the frame portion 11 are not particularly limited as long as they satisfy this requirement.

For example, the material of the frame portion 11 may be the same as or different from the material of the vibration portion 9. When the frame portion 11 and the vibration portion 9 are composed of the same material, it tends to be easier to form the two portions from integrated layers (an integrated member). The frame portion 11 and the vibration portion 9 may have (approximately) the same thickness (the illustrated example) or different thicknesses. Examples of configurations in which the frame portion 11 and the vibration portion 9 have different thicknesses include one in which the thickness of the vibration portion 9 (if the thickness is not uniform, for example, the maximum thickness) is less than the thickness of the frame portion 11 (if the thickness is not uniform, for example, the maximum thickness).

Whether the material of the frame portion 11 and the material of the vibration portion 9 are the same or different, the explanation of the material of the vibration portion 9 may be applied to the material of the frame portion 11. In a configuration in which the material of the frame portion 11 differs from the material of the vibration portion 9, the frame portion 11 need not include a piezoelectric material or may include a piezoelectric material of a type (and a cut angle) different from the type (and the cut angle) of the piezoelectric material of the vibration portion 9. As for a specific example of the material of the frame portion 11 different from the material of the vibration portion 9, the explanation of the specific examples of the material of the first substrate 3 and the second substrate 5 may be applied.

The frame portion 11, for example, surrounds the entire periphery of the vibration portion 9 (throughout) 360° in plan view. However, the frame portion 11 may be discontinuous in part. This discontinuous portion may be used, for example, for placing a conductor electrically connecting the inside and outside of the vibrator 1 in a configuration different from the illustrated example. For example, if the frame portion 11 extends over ¾ of a turn) (270° or more, ⅞ of a turn (315°) or more, or 15/16 of a turn (337.5°) or more of the length of the outer edge of the vibration portion 9 (or the angular range around the geometric center of the vibration portion 9), the frame portion 11 may be considered to surround the vibration portion 9.

The shape of the inner edge of the frame portion 11 in plan view may be a shape similar to or approximately similar to the shape of the outer edge of the vibration portion 9 (the illustrated example) or may be a completely different shape. Examples of the former include configurations in which both the shape of the outer edge of the vibration portion 9 and the shape of the inner edge of the frame portion 11 are rectangles (the illustrated example), circles, ellipses, and polygons (excluding rectangles). Examples of the latter include configurations in which, for example, the shape of the outer edge of the vibration portion 9 and the shape of the inner edge of the frame portion 11 are a circle and a rectangle, or an ellipse and a rectangle, respectively. From a different perspective, the distance d1 between the inner edge of the frame portion 11 and the outer edge of the vibration portion 9 in plan view may be approximately uniform along the entire periphery, but this is not essential.

The shape and dimensions of the outer edge of the frame portion 11 are, for example, approximately the same as the shape and dimensions of the outer edge of the vibrator 1 in plan view (mentioned already). The explanation of the relationship between the outer edge of the vibration portion 9 and the inner edge of the frame portion 11 in the previous paragraph may be applied to the relationship between the outer edge of the vibration portion 9 and the outer edge of the frame portion 11 by replacing the term “the inner edge of the frame portion 11” with the term “the outer edge of the frame portion 11”. In addition, the explanation of the relationship between the outer edge of the vibration portion 9 and the inner edge of the frame portion 11 in the previous paragraph may be applied to the relationship between the inner edge of the frame portion 11 and the outer edge of the frame portion 11 by replacing the term “the outer edge of the vibration portion 9” with the term “the inner edge of frame portion 11” and replacing “the inner edge of the frame portion 11” with the term “the outer edge of the frame portion 11”. As can be understood from this explanation, the width (the distance between the inner edge and the outer edge) of the frame portion 11 may be uniform or may be non-uniform in the peripheral direction.

The thickness of the frame portion 11 is, for example, approximately uniform throughout its entirety. From a different perspective, the front and back surfaces of the frame portion 11 are flat. However, for example, the front surface and/or back surface of the frame portion 11 may include a recess or a protrusion in part.

### (3.2. Conductors Located on Frame Portion)

The front and back surfaces (the +D3 side surface and the −D3 side surface) of the frame portion 11 are provided with, for example, the first-intermediate-side layer 25 and the second-intermediate-side layer 27 mentioned earlier (in the region excluding the region located on the vibration portion 9). The inner peripheral surfaces and the outer peripheral surfaces of the frame portion 11 are not provided with, for example, a conductor (for example, a conductor layer). From a different perspective, the regions of the first-intermediate-side layer 25 and the second-intermediate-side layer 27 located on the frame portion 11 are not connected to each other.

However, a conductor may be located on the inner peripheral surfaces and/or the outer peripheral surfaces partially or entirely in the peripheral direction. This configuration may electrically connect the regions of the first-intermediate-side layer 25 and the second-intermediate-side layer 27 located on the frame portion 11 to each other. Such a conductor may be, for example, a conductor layer stacked on the inner peripheral surfaces and/or the outer peripheral surfaces. Alternatively, a corner of the frame portion 11 in plan view may be provided with a castellation, and the conductor located in this castellation may achieve the electrical connection. Alternatively, the frame portion 11 may include a through-hole, similar to the first through-hole 9h, for electrically connecting the regions of the first-intermediate-side layer 25 and the second-intermediate-side layer 27 located on the frame portion 11 to each other.

Each of the first-intermediate-side layer 25 and the second-intermediate-side layer 27 is located on the frame portion 11, for example, throughout the entire perimeter in plan view (throughout 360° around the vibration portion 9 as the center). More specifically, the second-intermediate-side layer 27 and the first-intermediate-side layer 25 extend, for example, over the entire front and back surfaces of the frame portion 11, respectively. However, the first-intermediate-side layer 25 and the second-intermediate-side layer 27 may include portions away from the inner edge and/or outer edge of the frame portion 11 along all or part of the frame portion 11 in the peripheral direction. For example, the first-intermediate-side layer 25 (or the second-intermediate-side layer 27) may have, for example, a pattern of two or more lines extending parallel to one another along the frame portion 11, so that a region that is surrounded by the first-intermediate-side layer 25 and in which the first-intermediate-side layer 25 is not present may be formed.

As for each of the first-intermediate-side layer 25 and the second-intermediate-side layer 27, (part or all of) the region located on the frame portion 11 and (part or all of) of the region located on the vibration portion 9 may be composed of the same material and have the same thickness (the example in FIG. 3), or at least one of the material or the thickness may be different. In any case, the explanation of the material of the first-intermediate-side layer 25 and the second-intermediate-side layer 27 mentioned in the explanation of the conductors located on the vibration portion 9 may be applied to the material of the regions of the first-intermediate-side layer 25 and the second-intermediate-side layer 27 located on the frame portion 11.

### 4. First Substrate

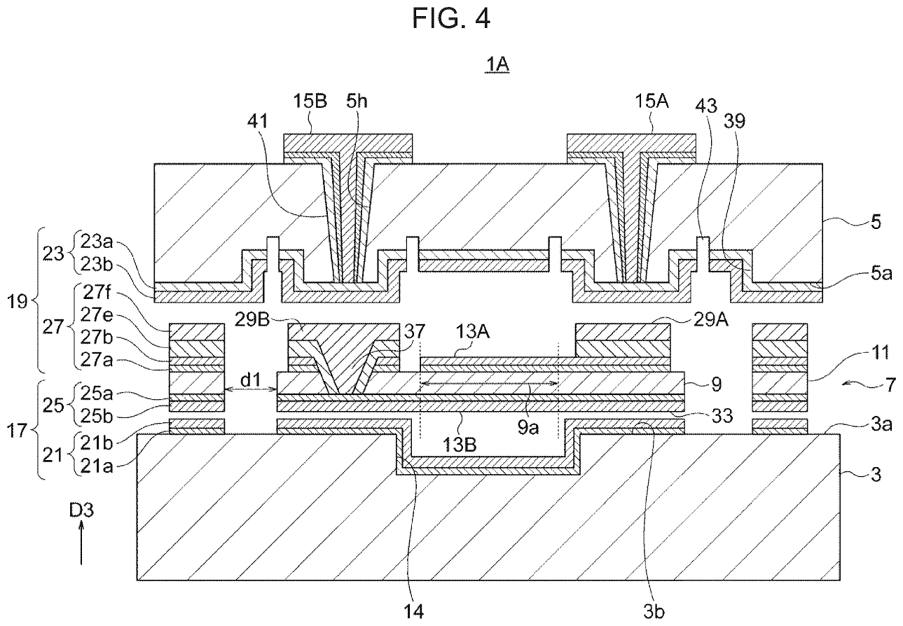

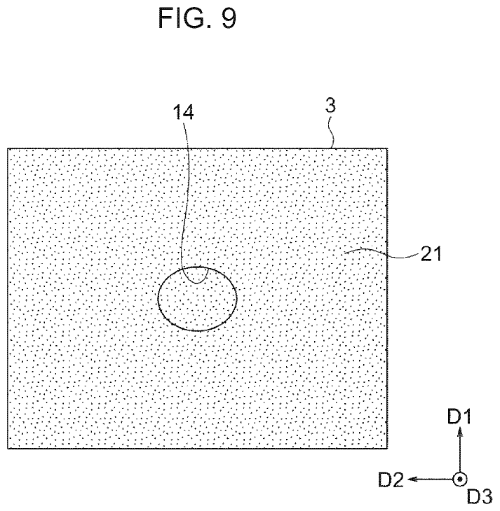

FIG. 4 is a cross-sectional view of specific configurations of the first-substrate-side layer 21 and the second-substrate-side layer 23, illustrating an example different from the one in FIG. 3. FIG. 9 is a plan view of specific configurations of the first substrate 3 and the first-substrate-side layer 21, illustrating an example different from the one in FIG. 1. In the following description, FIGS. 4 and 9 are also sometimes referred to in addition to FIGS. 1 to 3.

### (4.1. Material, Shape, and Dimensions of First Substrate)

The first substrate 3 is, for example, a flat-plate-shaped member with an approximately uniform thickness, except that it includes the first recess 14. However, the first substrate 3 may include not only the first recess 14 but also a recess and/or a protrusion on the +D3 side or the −D3 side as appropriate. The shape and dimensions of the first substrate 3 in plan view are, for example, approximately the same as the shape and dimensions of the vibrator 1 in plan view (mentioned earlier). The thickness of the first substrate 3 is not particularly limited. In the example in FIG. 3, the first substrate 3 is thicker than the second substrate 5 and the intermediate layer 7. In a relatively small vibrator 1, the thickness of the first substrate 3 is, for example, 50 μm or more and 200 μm or less.

When the first substrate 3 is thicker than the second substrate 5 and the intermediate layer 7, the intermediate layer 7 can be stably held when its thickness is reduced as described later. However, the thickness of the first substrate 3 is not limited to this relationship. For example, when the thickness of the first substrate 3 is approximately equal to the thickness of the second substrate 5, the overall stress balance in the vibrator 1 is suitable, reducing the warp. This also reduces the effects of the stress generated when the vibrator 1 is mounted.

The material of the first substrate 3 is not particularly limited. For example, the first substrate 3 may be integrally formed by using an insulator, a semiconductor, or the material the same as and/or similar to that of the intermediate layer 7, or may be formed by stacking different materials. Examples of the latter configuration include one including a first layer composed of an insulator or a semiconductor and a metal layer (from a different perspective, a shield and/or a reinforcement material) stacked on the −D3 side of the first layer. Another example is a configuration in which the first substrate 3 is composed of a multilayer substrate. The insulator may be composed of an inorganic material (for example, quartz crystal or a ceramic) or an organic material (for example, a resin). Examples of the semiconductor include silicon (Si) and germanium (Ge).

The semiconductor composing the first substrate 3 is, for example, an intrinsic semiconductor without lattice defects (in a broad sense). For example, a semiconductor basically does not include impurities and/or atomic disorder. However, the semiconductor may include lattice defects. For example, in a configuration different from the illustrated example, part of the first substrate 3 may be composed of a p-type semiconductor or a n-type semiconductor containing impurities so as to serve as an electronic element or contribute to the electrical connection between the inside and outside of the vibrator 1.

The shape and dimensions of the first recess 14 in plan view are not particularly limited. For example, the planar shape of the first recess 14 may be the same as, similar to, or approximately similar to the shape of the first excitation electrode 13A (the example in FIG. 1) or may be completely different (see FIG. 7). In perspective plan view, the first recess 14 and the first excitation electrode 13A may completely overlap each other, the former may be within a part of the latter, the latter may be within a part of the former (the example in FIG. 3), or they may include regions not overlapping each other. In perspective plan view, the geometric center of the first recess 14 may be aligned with the geometric center of the first excitation electrode 13A, but this is not essential.

In any configuration in the previous paragraph, the explanation of the shape and dimensions of the first excitation electrode 13A may be applied to the explanation of the shape and dimensions of the first recess 14 in plan view unless a contradiction or the like occurs. Just to be sure, part of the applicable statements is extracted and rewritten as follows: The planar shape of the first recess 14 may be a circle (the example in FIG. 1), an ellipse (the example in FIG. 9), a rectangle (for example, a rectangle or a square, see FIGS. 7 and 8A), or a polygon (excluding rectangles). The ratio between the length in the longitudinal direction and the length in the lateral direction, for example, may range 1.14:1 to 1.39:1, or may be 1.26:1. This ratio may be applied to, for example, a configuration in which the direction of thickness shear vibration (the X-axis direction) corresponds to the longitudinal direction.

The shape and dimensions (for example, the depth) of the vertical cross section (the cross section parallel to the D3 direction) of the first recess 14 are not particularly limited. For example, in the vertical cross section of the first recess 14, the side surfaces of the first recess 14 may be approximately parallel to the D3 direction or may be inclined relative to the D3 direction. With the inclination side surfaces, the diameter of the first recess 14 may increase or decrease in the +D3 direction. For example, the depth of the first recess 14 may have the minimum depth so that the second excitation electrode 13B will not come into contact with a bottom surface (in the illustrated example, more specifically, the region of the aforementioned first-substrate-side layer 21 located in the bottom surface of the first recess 14) of the first recess 14 in intended use or may be deeper than the minimum depth. For example, the depth of the first recess 14 may be less than or greater than or equal to ½ of the thickness of the first substrate 3.

### (4.2. Conductors Located on First Substrate)

The surface on the +D3 side (the intermediate layer 7 side) of the first substrate 3 is provided with, for example, the aforementioned first-substrate-side layer 21. The outer peripheral surfaces (side surfaces) and the −D3 side surface of the first substrate 3 are not provided with, for example, a conductor (for example, a conductor layer).

However, the first substrate 3 may include a conductor other than the first-substrate-side layer 21. For example, a metal layer that functions as a shield and/or a reinforcement material may be stacked on the −D3 side surface (as already mentioned, this metal layer may be regarded as part of the first substrate 3). For example, a castellation may be formed at a corner of the first substrate 3 in plan view, and this castellation may include a conductor. As already mentioned, the first substrate 3 may be provided with an external electrode 15, and the external electrode 15 may be exposed on the −D3 side surface. Note that when the first substrate 3 is provided with an external electrode 15, the first substrate 3 may be thinner than the second substrate 5 from the viewpoint of forming a through-hole. In this case, the configurations of the conductors on the −D3 side of the vibration portion 9 and the conductors on the first substrate 3 can be inferred from the configurations of the conductors on the +D3 side of the vibration portion 9 and the conductors of the second substrate 5 in the illustrated example.

The first-substrate-side layer 21 contributes to, for example, joining the vibration portion 9 to the first substrate 3. The first-substrate-side layer 21 contributes to, for example, joining the entire perimeter of the frame portion 11 to the first substrate 3 and enclosing the vibration portion 9. The shape and dimensions of the first-substrate-side layer 21 in plan view are not particularly limited as long as those provide the function mentioned above.

In the example illustrated in FIG. 1, the first-substrate-side layer 21 is composed of two separate regions: an inner region 21e that contributes to the joining of (and the electrical connection between) the vibration portion 9 and the first substrate 3, and an outer region 21f that contributes to the joining of the frame portion 11 and the first substrate 3. This, for example, reduces the probability that the multifunctional electrode 33 is unintentionally electrically connected to another conductor. However, a configuration in which the first-substrate-side layer 21 is not separated into the inner region 21e and the outer region 21f is also possible, as in another example illustrated in FIG. 9. In other words, the entire first-substrate-side layer 21 may be composed of one solid pattern.

The inner region 21e has, for example, a shape that approximately matches the vibration portion 9 in perspective plan view (for example, a shape in which 90% or more of each area overlaps each other). However, for example, the inner region 21e may extend outward of the vibration portion 9 within a range not overlapping the frame portion 11 (or the region of the first-intermediate-side layer 25 located on the frame portion 11) in perspective plan view or may be located further inward than the outer edge of the vibration portion 9 while maintaining the overlapping with the multifunctional electrode 33. In any configuration mentioned above, the explanation of the shape and dimensions of the vibration portion 9 in plan view may be applied to the shape and dimensions of the inner region 21e unless a contradiction or the like occurs.

The outer region 21f has, for example, a shape that approximately matches the frame portion 11 in perspective plan view (for example, a shape in which 90% or more of each area overlaps each other). However, for example, the outer region 21f may extend inward of the inner edge of the frame portion 11 within a range not overlapping the vibration portion 9 (or the multifunctional electrode 33) in perspective plan view or may extend outward of the outer edge of the frame portion 11. In either configuration mentioned above, the explanation of the shape and dimensions of the frame portion 11 in plan view may be applied to the shape and dimensions of the outer region 21f unless a contradiction or the like occurs.

The first-substrate-side layer 21 (the outer region 21f) illustrated in FIG. 1 is away from the outer edge of the first substrate 3 throughout the entire periphery. This, for example, reduces the probability that the multifunctional electrode 33 is unintentionally electrically connected to another conductor. However, the first-substrate-side layer 21 may extend to the outer edge of the first substrate 3 as in another example illustrated in FIG. 9.

The first-substrate-side layer 21 (the inner region 21e) may include a portion stacked on the inner surface of the first recess 14, but this is not essential. Examples of the former configuration include one in which the first-substrate-side layer 21 is located on the bottom surface of the first recess 14 (for example, the entire bottom surface) (the example in FIGS. 1 and 3), one in which the first-substrate-side layer 21 is located on the bottom surface and outer peripheral surface out of the inner surfaces of the first recess 14 (for example, the entire bottom surface and the entire outer peripheral surface) (the example in FIG. 4), and one in which the first-substrate-side layer 21 is located on the outer peripheral surface of the first recess 14 (for example, the entire outer peripheral surface).

The material, the thickness, and the configuration in the thickness direction of the first-substrate-side layer 21 are not particularly limited. For example, the first-substrate-side layer 21 may be composed of the same material and have the same thickness throughout the entirety (the example in FIG. 3) or may be composed of different materials and/or have different thicknesses depending on the regions. Examples of the latter configuration include one in which the region overlapping the vibration portion 9 and the region overlapping the frame portion 11 (for example, the inner region 21e and outer region 21f) are composed of different materials and/or have different thicknesses.

For example, the first-substrate-side layer 21 may be composed of a single metal layer or two or more metal layers (the example in FIG. 3). In the example in FIG. 3, the first-substrate-side layer 21 includes a lower layer 21a in contact with (directly stacked on) the first substrate 3 and an upper layer 21b stacked on the lower layer 21a. The explanation of the lower layer 25a and the upper layer 25b of the first-intermediate-side layer 25 may be applied to the lower layer 21a and the upper layer 21b by replacing the symbol “25” with “21” and the term “vibration portion 9” with “first substrate 3”.

The surface layers (the upper layer 25b and the upper layer 21b in the example in FIG. 3) of the first-substrate-side layer 21 and the first-intermediate-side layer 25 configured to be joined to each other may be composed of the same material or different materials. In the former configuration, the boundary between the first-substrate-side layer 21 and the first-intermediate-side layer 25 (the upper layer 25b and the upper layer 21b) may be identified in a completed vibrator 1 by observing it with a transmission electron microscope (TEM) or the like, or a configuration in which the boundary cannot be identified is also possible. The explanation in this paragraph may be applied to the second-substrate-side layer 23 and the second-intermediate-side layer 27.

### 5. Second Substrate

### (5.1. Material, Shape, and Dimensions of Second Substrate)

The second substrate 5 is, for example, an approximately flat-plate-shaped member. The shape and dimensions of the second substrate 5 in plan view are, for example, approximately the same as those of the vibrator 1 in plan view (mentioned above).

However, in the example illustrated in FIGS. 2 and 3, the second substrate 5 includes the second recess 39 in the second surface 5a on the −D3 side. For example, the second recess 39, as the first recess 14, faces the excitation portion 9a of the vibration portion 9, and this makes the vibration of the excitation portion 9a easier. The second recess 39 is larger than the region facing the excitation portion 9a. This can, for example, reduce the joint area between the second surface 5a and the intermediate layer 7, increasing the contact pressure when the two portions are joined.

However, the second surface 5a may have a flat shape without the second recess 39. Alternatively, the second substrate 5 may include not only the second recess 39 but also a recess and/or a protrusion on the +D3 side or the −D3 side as appropriate. Note that in a configuration in which the second surface 5a is flat, the probability of the excitation portion 9a coming into contact with the second surface 5a may be reduced by various methods. Such examples are as follows: The thickness of the excitation portion 9a may be reduced in the −D3 direction such that the excitation portion 9a is lower than the frame portion 11. Of the second-intermediate-side layer 27, the region contributing to the joining of the intermediate layer 7 and the second surface 5a may be thicker than the first excitation electrode 13A (the example in FIG. 3). For example, in a configuration in which the vibration portion 9 uses SAW, and the vibration propagates on the −D3 side surface, the +D3 side surface of the excitation portion 9a may be joined to the second surface 5a.

From a different perspective, the second surface 5a includes a frame-shaped region 5aa configured to be joined to the frame portion 11, the second recess 39 surrounded by the frame-shaped region 5aa, and raised portions 5ab surrounded by the second recess 39, as indicated by the symbols in FIG. 2. A top surface (the −D3 side surface) of each raised portion 5ab includes a pad region 5ac configured to be joined to the corresponding pad electrode 29. The following describes examples of the shape and dimensions of each part.

For example, the frame-shaped region 5aa has a shape overlapping approximately the entire frame portion 11 (for example, 90% or more) in perspective plan view. Part or all of the inner edge of the frame-shaped region 5aa (from a different perspective, the edge portions of the second recess 39) may be aligned with the inner edge of the frame portion 11, may be located inside the inner edge of the frame portion 11 within a range not overlapping the vibration portion 9 (or the excitation portion 9a), or may be located outside the inner edge of the frame portion 11 within a range in which the overlap between the frame-shaped region 5aa and the frame portion 11 is maintained. Part or all of the outer edge of the frame-shaped region 5aa (from a different perspective, the outer edge of the second substrate 5) may be aligned with the outer edge of the frame portion 11, may be located inside the outer edge of the frame portion 11 within a range in which the overlap between the frame-shaped region 5aa and the frame portion 11 is maintained, or may be located outside the outer edge of the frame portion 11. In any configuration mentioned above, the explanation of the shape and dimensions of the frame portion 11 in plan view may be applied to the shape and dimensions of the frame-shaped region 5aa unless a contradiction or the like occurs.

The raised portions Sab have, for example, shapes and dimensions that allow them to approximately overlap the pad electrodes 29 in perspective plan view. More specifically, part or all of the outer edge of each raised portion 5ab may be aligned with, may be located outside (the example in FIG. 3), or may be located inside the outer edge of the corresponding pad electrode 29. In any case, the explanation of the shapes and dimensions of the pad electrodes 29 in plan view may be applied to the shapes and dimensions of the raised portions 5ab unless a contradiction or the like occurs. The positions, in the D3 direction, of the top surfaces (the −D3 side surfaces) of the raised portions 5ab are, for example, the same as the position, in the D3 direction, of the −D3 side surface of the frame-shaped region 5aa. However, these positions may differ.

The explanation of the shape and dimensions of the second recess 39 in plan view is the opposite version of the above explanation of the shapes and dimensions of the frame-shaped region 5aa and the raised portions 5ab in plan view and thus is omitted. The side surfaces of the second recess 39 may be approximately parallel to the D3 direction or may be inclined relative to the D3 direction. The diameter of the second recess 39 may either increase or decrease in the −D3 direction due to the inclined side surfaces. The depth of the second recess 39 is not particularly limited. For example, the depth of the second recess 39 may have the minimum depth so that the first excitation electrode 13A will not come into contact with a bottom surface (in the illustrated example, more specifically, the region of the second-substrate-side layer 23 located in the bottom surface of the second recess 39) of the second recess 39 in intended use or may be deeper than the minimum depth. For example, the depth of the second recess 39 may be less than or greater than or equal to ½ of the thickness of the second substrate 5.

The vibration portion 9 and the second substrate 5 are joined to each other only by the raised portions 5ab. This configuration allows the space between the +D3 side of the excitation portion 9a and the second recess 39 to communicate with the space between the outer side portion of the vibration portion 9 and the inner peripheral surfaces of the frame portion 11. This configuration, for example, reduces foreign objects attaching to the excitation portion 9a.

The thickness of the second substrate 5 is not particularly limited. In the example in FIG. 3, the second substrate 5 is thicker than the intermediate layer 7 and thinner than the first substrate 3. In a relatively small vibrator 1, the thickness of the second substrate 5 is, for example, 20 μm or more and 100 μm or less.

Since the external electrodes 15 are located on the second substrate 5 in this example, the second substrate 5 includes through-holes extending through the second substrate 5 in the D3 direction. Since the second substrate 5 described above is thinner than the first substrate 3, forming the through-holes is easy, increasing the productivity. This also improves the continuity of the extension conductors 41 located in the through-holes.

The material of the second substrate 5 is not particularly limited. The foregoing explanation of the material of the first substrate 3 may be applied to the second substrate 5. Just to be sure, part of the applicable statements is extracted and rewritten as follows: The second substrate 5 may be integrally formed by using an insulator or a semiconductor, or may be formed by stacking different materials. The insulator may be composed of an inorganic material (for example, quartz crystal or a ceramic) or an organic material (for example, a resin). Examples of the semiconductor include silicon (Si) and germanium (Ge).

### (5.2. Conductors Located on Second Substrate)

The second substrate 5 is provided with, for example, the following conductors as illustrated in FIGS. 1 to 3: the second-substrate-side layer 23 located on the −D3 side surface (the intermediate layer 7 side surface) of the second substrate 5, the external electrodes 15 located on the +D3 side surface of the second substrate 5, and the extension conductors 41 located in the second through-holes 5h extending through the second substrate 5 and electrically connecting the second-substrate-side layer 23 and the external electrodes 15.

However, the second substrate 5 may be provided with a conductor other than those mentioned above. For example, castellations may be formed at corners of the second substrate 5 in plan view, and the castellations may include conductors. These conductors may contribute to the electrical connection between the second-substrate-side layer 23 and the external electrodes 15 and may be provided instead of or in addition to the extension conductors 41.

The second-substrate-side layer 23 extends, for example, approximately over the entire second surface 5a. From a different perspective, the second-substrate-side layer 23 includes the region stacked in the frame-shaped region 5aa, the region stacked on the bottom surface of the second recess 39, and the regions stacked on the top surfaces of the raised portions 5ab (from a different perspective, the pad regions 5ac). The second-substrate-side layer 23 need not be stacked on the side surfaces of the second recess 39 (the example in FIG. 3) or may be stacked on them (the example in FIG. 4).

The region stacked in the frame-shaped region 5aa contributes to the joining of the frame portion 11 and the second substrate 5. The regions stacked on the top surfaces of the raised portions 5ab contribute to the joining of the vibration portion 9 and the second substrate 5 and also contribute to the electrical connection between the pad electrodes 29 and the external electrodes 15. The region stacked on the bottom surface of the second recess 39 (and the side surfaces) can function as, for example, a shield and/or a reinforcement material.

The second-substrate-side layer 23 need not necessarily extend over the entire second surface 5a. For example, a configuration in which the second-substrate-side layer 23 includes the region stacked in the frame-shaped region 5aa and the regions stacked in the pad regions 5ac and does not include the region stacked on the bottom surface of the second recess 39 is also possible. For example, the second-substrate-side layer 23 may be away from the edge portions of the second surface 5a.

The material, the thickness, and the configuration in the thickness direction of the second-substrate-side layer 23 are not particularly limited. For example, the second-substrate-side layer 23 may be composed of the same material and have the same thickness throughout the entirety (the example in FIG. 3) or may be composed of different materials and/or have different thicknesses depending on the regions. Examples of the latter configuration include one in which the region configured to be joined to the intermediate layer 7 and the region configured not to be joined to the intermediate layer 7 are composed of different material and/or have different thicknesses.

For example, the second-substrate-side layer 23 may be composed of a single metal layer or two or more metal layers (the example in FIG. 3). In the example in FIG. 3, the second-substrate-side layer 23 includes a lower layer 23a in contact with (directly stacked on) the second substrate 5 and an upper layer 23b stacked on the lower layer 23a. The explanation of the lower layer 25a and the upper layer 25b of the first-intermediate-side layer 25 may be applied to the lower layer 23a and the upper layer 23b by replacing the symbol “25” with “23” and the term “vibration portion 9” with “second substrate 5”.

The positions, shapes, and dimensions of the external electrodes 15 (viewed from the outside) were already mentioned in the explanation of the mounting configuration of the vibrator in Section 1.2. The external electrodes 15 may be composed of the conductor layer stacked on the +D3 side surface of the second substrate 5, may be composed of the +D3 side surfaces of the extension conductors 41 having pillar shapes passing through the second substrate 5, or may include a configuration in which such a distinction is difficult.

In a configuration in which the external electrodes 15 include the conductor layer stacked on the +D3 side surface of the second substrate 5, the conductor layer may be composed of a single metal layer or two or more metal layers (the example in FIG. 3). In the example in FIG. 3, although no specific symbols are assigned, the conductor layer of each external electrode 15 is composed of three metal layers. Specific materials for these are not particularly limited. For example, for the material of the layer farthest in the +D3 direction, the material for the upper layer 25b shown as an example may be used. For the materials of the other two layers, the material for the lower layer 25a shown as an example may be used.

As already mentioned in the explanation of the connection conductor 37, the configuration of the extension conductor 41 is not particularly limited (for example, may be a pillar shape or a layer shape). The shape and dimensions of the extension conductor 41 (the second through-hole 5h) is also not particularly limited. For example, the second through-hole 5h may have a right cylinder shape or a tapered shape the diameter of which decreases in the +D3 direction or the −D3 direction. The shape of the horizontal cross section (D1-D2 cross section) of the second through-hole 5h may be, for example, a circle, an ellipse, a rectangle, or a polygon (excluding rectangles).

The positions of the extension conductors 41 and the external electrodes 15 are also not particularly limited. In the example in FIG. 3, the extension conductors 41 and the external electrodes 15 are located immediately above the pad regions 5ac configured to be joined to the pad electrodes 29 out of the second surface 5a of the second substrate 5. This, for example, simplifies the configuration of the second substrate 5. This, for example, also reduces the probability of the deterioration in the sealing property due to the second through-holes 5h because the second through-holes 5h are located at positions that overlap the vibration portion 9 and do not overlap the frame portion 11. Details of the positional relationship between the first through-holes 9h and the second through-holes 5h and other conditions in the example in FIG. 3 will be described in the Section 7.2.

Unlike the illustrated example, the external electrodes 15 (and the extension conductors 41) may be located at positions other than the positions immediately above the pad regions 5ac. Examples of other positions include positions not overlapping the pad electrodes 29 but overlapping the vibration portion 9, positions overlapping the region between the vibration portion 9 and the frame portion 11, positions overlapping the frame portion 11, and/or positions outside the frame portion 11. In a configuration in which the external electrodes 15 (and the extension conductors 41) do not overlap the vibration portion 9, the probability that the stress generated when the vibrator 1 is mounted on a circuit board (not illustrated) or the like is transmitted through the external electrodes 15 and the extension conductors 41 to the vibration portion 9 is low, for example.

In a configuration in the previous paragraph, for example, the second-substrate-side layer 23 may include traces extending from positions overlapping the pad region 5ac to appropriate positions, and the extension conductors 41 and the external electrodes 15 may be located at the appropriate positions. Alternatively, for example, the traces mentioned above may extend to the castellations previously mentioned, and the conductors located at the castellations may electrically connect the external electrodes 15 and the pad electrodes 29. Alternatively, the second substrate 5 may be composed of a multilayer substrate, and the external electrodes 15 may be located at appropriate positions.

### 6. Positional Relationship and Other Conditions Among Constituents

### (6.1. Relationship Between First Recess and Vibration Portion)

The vibration portion 9 may face, for example, the entire first recess 14 (the example in FIGS. 1 to 3). In addition, the first substrate 3 and the vibration portion 9 may be joined to each other along the entire periphery of the first recess 14 so as to close (seal) the first recess 14.

However, a configuration in which the vibration portion 9 does not close the first recess 14 and a configuration in which the vibration portion 9 does not face the entire first recess 14 are also possible. Such examples are shown below.

FIG. 7 is a plan view illustrating an example of a configuration in which the vibration portion 9 does not seal the first recess 14. Specifically, this figure illustrates a view of the first substrate 3 and the vibration portion 9 from the +D3 side (illustration of the second substrate 5 and the frame portion 11 is omitted).

In this example, the vibration portion 9 does not face the entire first recess 14. Hence, the first substrate 3 and the vibration portion 9 are not joined throughout the entire periphery of the first recess 14. In such a configuration, for example, since the space in the first recess 14 communicates with the space on the +D3 side of the vibration portion 9 (for example, inside the second recess 39), the atmospheric pressures in the two spaces are equal or almost equal. This, for example, reduces the effects of atmospheric pressure difference on the vibration.

In a configuration in which the vibration portion 9 does not face the entire first recess 14, the shapes and the dimensions of the two and the positional relationship between the two are not particularly limited. From a different perspective, the shapes and dimensions of the portions facing each other and the portions not facing each other are not particularly limited. From a further different perspective, the shape and dimensions of the region of the vibration portion 9 supported by (and/or joined to) the first substrate 3 in the outer periphery of the first recess 14 are not particularly limited.

For example, in the example in FIG. 7, the first recess 14 includes two portions that are not covered by the vibration portion 9 on both sides of the vibration portion 9 in the D1 direction. From a different perspective, the first substrate 3 includes two separate regions that support the vibration portion 9 in the periphery of the first recess 14. Unlike the illustrated example, there may be one portion or three or more portions of the first recess 14 that are not covered by the vibration portion 9. The area of the portion of the first recess 14 (more specifically, the opening (the upper portion)) covered by the vibration portion 9 (when the vibration portion 9 include third through-holes 9k described later, the area excluding the area of the third through-holes 9k) may be, for example, less than ½ of the area of the first recess 14, or may be ½ or more, ⅔ or more, ⅘ or more, or 9/10 or more of the area of the first recess 14.

For example, the range, in the peripheral direction, of the overlapping region where the vibration portion 9 overlaps the outer periphery of the first recess 14 (the outer peripheral region 3b) (or the joint region where the two portions are joined) is not particularly limited. For example, the overlapping region (the joint region) may extend over 30° or more, 45° or more, 75° or more, 100° or more, 150° or more, ½ of a turn) (180° or more, ¾ of a turn) (270° or more, ⅞ of a turn) (315° or more, or 15/16 of a turn) (337.5° with reference to the length of the outer edge of the vibration portion 9 or the first recess 14 (or the angular range around the geometric center of the vibration portion 9 or the first recess 14). When the overlapping region (the joint region) extends over 180° or more, the overlapping region (the joint region) may be considered to surround the center of the vibration portion 9 or the first recess 14. As indicated by the two arrows a5 in the example in FIG. 7, the overlapping region (the joint region) does not need to be continuous, and the configuration mentioned above includes ones in which the total angular ranges of the regions is 180° or more.

FIG. 8A is a plan view illustrating another example of a configuration in which the vibration portion 9 does not seal the first recess 14, in the same manner as FIG. 7. FIG. 8B is a cross-sectional view taken along line VIIIb-VIIIb in FIG. 8A (which, however, illustrates only a region including the first recess 14).

In this example, the vibration portion 9 has a size facing the entire first recess 14. Specifically, the vibration portion 9 overlaps (is joined to) the outer periphery of the first recess 14 (the outer peripheral region 3b) throughout the entire periphery around the center of the vibration portion 9 (from a different perspective, the first recess 14). The vibration portion 9 includes third through-holes 9k extending through the vibration portion 9 in the thickness direction. This allows the inside of the first recess 14 to communicate with the space on the +D3 side of the vibration portion 9 (the second recess 39).

The number, positions, shapes, and dimensions of the third through-holes 9k are not particularly limited. For example, the third through-holes 9k may be located in either the arrangement region where the first-intermediate-side layer 25 and/or the second-intermediate-side layer 27 is present or the non-arrangement region where neither of them is present. The third through-holes 9k may also serve as the first through-holes 9h that contribute to electrical connection, but this is not essential. The shape of the third through-hole 9k in plan view may be one other than a slit shape (the illustrated example) or may be a slit shape.

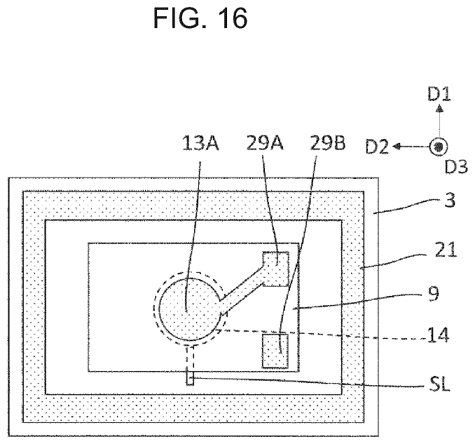

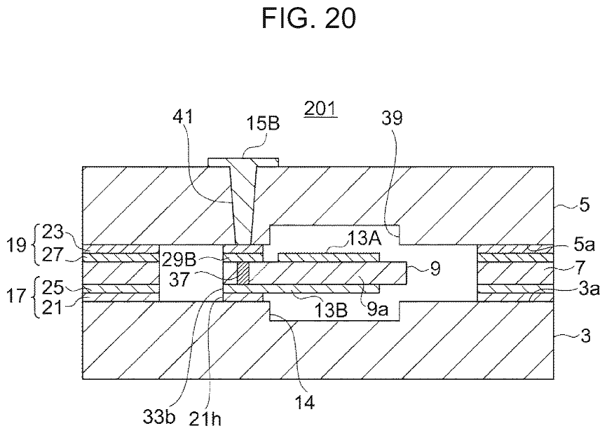

The communication between the first recess 14 and the space on the +D3 side of the vibration portion 9 (the second recess 39) may be achieved by a method other than the one mentioned above. For example, in a configuration in which the vibration portion 9 faces the entire first recess 14, the multifunctional electrode 33 and/or the first-substrate-side layer 21 may include a slit extending from an edge portion of the first recess 14 to an outer edge of the vibration portion 9 so that the first recess 14 can communicate with a space on an outer peripheral side of the vibration portion 9 (a gap between the vibration portion 9 and the frame portion 11). Alternatively, the first substrate 3 may include a slit SL integrally formed with the first recess 14 and extending to an outer edge of the vibration portion 9 (see FIG. 16). The communication between the first recess 14 and the space on the +D3 side of the vibration portion 9 (the second recess 39) may be achieved by a portion of the vibration portion 9 outside the first recess 14 in plan view. Alternatively, the communication between the first recess 14 and the outside may be achieved by employing a support structure in a cantilever manner (FIG. 20) described later.

### (6.2. Gap Between Vibration Portion and Frame Portion)

The specific distance d1 (FIG. 3) between the outer edge of the vibration portion 9 and the inner edge of the frame portion 11 is not particularly limited. For example, the distance d1 may be less than or greater than or equal to ½ of the width of the frame portion 11 (the width from the inner edge to the outer edge). For example, the distance d1 may be set in consideration of the wavelength of unnecessary vibration generated in the vibration portion 9. A specific example is shown below.

When an alternating current voltage is applied to the vibration portion 9, not only the thickness shear vibration intended to be used but also unnecessary vibration is generated in the vibration portion 9. Examples of unnecessary vibration include flexural vibration, thickness vibration (thickness extensional vibration), and contour shear vibration. In flexural vibration, for example, the vibration portion 9 is bent in the D3 direction. In thickness vibration, for example, the vibration portion 9 expands and contracts in the thickness direction (the D3 direction). In contour shear vibration, for example, side surfaces of the vibration portion 9 facing each other in plan view slide relative to each other.

Unnecessary vibration resonates at frequencies (wavelengths) defined by specific dimensions of the vibration portion 9. From a different perspective, unnecessary vibration generates a standing wave with its nodes or antinodes at the end portions of the vibration portion 9 in the vibration direction. This standing wave is assumed to have a wavelength of λ (the standing wave may be any one of various kinds of unnecessary vibration). The distance d1 may be set to n×λ/4 (n is a natural number). When it is stated that d1 is equal to n×λ/4, the statement allows for an error margin of ±λ/16 or ±λ/32.

In each of the various modes (flexural vibration, thickness vibration, and contour shear vibration) of unnecessary vibration, standing waves of various orders can be generated. The wavelength λ mentioned above is assumed to be the wavelength of the vibration which is most likely to be coupled to the thickness shear vibration to be used, out of the standing waves of various orders propagated in the direction in which the distance d1 is measured. The wavelength A of such a standing wave may be determined by, for example, a simulation calculation or an experiment. For example, the relationship mentioned in the previous paragraph may hold throughout the entire periphery of the vibration portion 9 or may hold in part or most (for example, ½ or more or ¾ or more) of the periphery.

As already mentioned, the vibration portion 9 and the frame portion 11 are apart from each other along the entire periphery. This statement is on the assumption that the gap between the two portions is, for example, a space in a vacuum state or in which a gas is present. However, in the gap of the two portions, a material may be interposed that allows larger relative displacement between the vibration portion 9 and the frame portion 11 than in a configuration in which the vibration portion 9 and the frame portion 11 are integrally formed (from a different perspective, a configuration in which the two portions are connected by the material the same as those of the two portions). The material mentioned above has, for example, a lower elastic modulus (for example, Young's modulus) than the materials of the vibration portion 9, the frame portion 11, and the first substrate 3.

### (6.3. Relationship of Dimensions and Other Conditions Among Various Layers)

The relationship among the dimensions (for example, the size and the thickness) of the various layers (for example, 3, 5, 7, 17, and 19) is not particularly limited.

For example, in the example in FIG. 3, in perspective plan view, the outer edge of the first substrate 3 is located outside the outer edge of the second substrate 5 throughout the entire periphery (in other words, the former is larger than the latter), and the outer edge of the second substrate 5 is located outside the outer edge of the intermediate layer 7 throughout the entire periphery (in other words, the former is larger than the latter). Unlike the example in FIG. 3, for example, a configuration in which the outer edge of the first substrate 3 is located outside the outer edges of the intermediate layer 7 and the second substrate 5 throughout the entire periphery, and in which the outer edge of the intermediate layer 7 is located outside the outer edge of the second substrate 5 throughout the entire periphery is also possible. Alternatively, the positional relationship among the outer edges of these three layers may differ depending on the position in the peripheral direction. The degree of the difference in size is also not particularly limited.

When the outer edge of the first substrate 3 is located outside the outer edge of the intermediate layer 7, cutting with a dicing machine at positions outside the outer edge of the intermediate layer 7 in singulation into individual pieces makes it less likely that the stress generated when cutting with a dicing machine is exerted on the vibration portion 9 and the joint portion between the intermediate layer 7 and the first substrate 3. Thus, the vibrator 1 with high reliability can be provided.

For example, in the example in FIG. 3, when the recesses (14 and 39) are ignored, the first substrate 3 is thicker than the second substrate 5, and the second substrate 5 is thicker than the intermediate layer 7. Unlike the example in FIG. 3, for example, the second substrate 5 may be thicker than the first substrate 3. For example, in the example in FIG. 3, the first metal layer 17 and the second metal layer 19 are thinner than the first substrate 3, the second substrate 5, and the intermediate layer 7. Unlike the example in FIG. 3, one of the metal layers may be thicker than the intermediate layer 7 or the like. For example, the thickness of the second metal layer 19 may be greater than (the example in FIG. 3), equal to, or less than the thickness of the first metal layer 17. When the various layers have differences in the thickness as mentioned above, the degree of the difference is also not particularly limited.

In perspective plan view, the geometric center of the first recess 14 may be aligned with the geometric center of the first substrate 3, but this is not essential. The geometric center of the first substrate 3 and/or the first recess 14 may be aligned with the geometric center of the vibration portion 9 and/or the excitation portion 9a, but this is not essential. When the wavelength of the thickness shear vibration (in other words, the vibration intended to be used) is assumed to be 2, and for example, the distance between the geometric centers is λ/4 or less, the two geometric centers may be considered to be aligned.

### 7. Details of Electrical Connection Between Vibration Portion and Second Substrate

### (7.1. Grooves in Second Substrate)

FIG. 10 is an enlarged view of region X in FIG. 2. FIG. 11 is an enlarged view of an area including the second pad electrode 29B in FIG. 3. Note that in FIG. 11, illustration of the lower layer 21a of the first metal layer 17 is omitted (or the lower layer 21a is actually not present). Illustration to distinguish the lower layer 27a, the upper layer 27b, and the first joint layer 27e from one another is omitted (or actually one layer is present instead of the three layers). Note that the following description is based on an example of the connection of the second pad electrode 29B, but the same and/or similar description can be applied to the connection of the second inspection electrode 31B.

As illustrated in these figures, the top surface of the raised portion 5ab may include an annular groove 43 surrounding the pad region 5ac configured to be connected to the second pad electrode 29B. The second-substrate-side layer 23 is not present in the groove 43. This configuration separates the portion of the second-substrate-side layer 23 where the pad region Sac is located from the other portion of the second-substrate-side layer 23 and enables different electric potentials to be applied to these portions.

In perspective plan view, the outer edge of the top surface of the raised portion 5ab may be located, for example, outside the outer edge of the second pad electrode 29B throughout the entire periphery (in other words, the top surface may be larger than the second pad electrode 29B). As indicated by arrow a1 in FIG. 11, the inner edge of the groove 43 may be located, for example, outside the outer edge of the second pad electrode 29B throughout the entire periphery (in other words, the region surrounded by the groove 43 may be larger than the second pad electrode 29B). The positional relationship (the relationship between the sizes of the areas) mentioned above, for example, reduces the probability that the portions of the second-substrate-side layer 23 to which different electric potentials are to be applied are short-circuited by the second pad electrode 29B.

The specific shape and dimensions of the groove 43 are not particularly limited. For example, the groove 43 may have a shape similar to or approximately similar to the shape of the outer edge of the top surface of the raised portion 5ab and/or the outer edge of the pad electrode 29 or may have a totally different shape. For example, the distance between the outer edge of the groove 43 and the outer edge of the raised portion 5ab and the distance between the inner edge of the groove 43 and the second pad electrode 29B are not particularly limited. The depth of the groove 43 may be the same as the depth of the second recess 39 (the illustrated example) or may differ from it. The width of the groove 43 may be uniform, but this is not essential. The side surface of the groove 43 may be parallel to the D3 direction or may be inclined relative to the D3 direction.

As illustrated in FIG. 4, the groove 43 may be formed around each raised portion 5ab. However, the groove 43 is not essential. Even if the groove 43 is not present, the manner of patterning of the second-substrate-side layer 23 can separate the portion joined to the second pad electrode 29B from the other portions.

### (7.2. Positional Relationship Between First Through-Holes and Second Through-Holes)

As illustrated in FIG. 11, the following description is based on the assumption that the second through-hole 5h is located immediately above the pad region 5ac. In this configuration, as indicated by arrows a2 and a3, the first through-hole 9h and the second through-hole 5h may include portions not overlapping each other in perspective plan view. In this case, for example, the structural strength of the configuration composed of the vibration portion 9 and the second substrate 5 will be higher than in a configuration in which one of the through-holes is within the other through-hole (this configuration is also included in the techniques according to the present disclosure). Note that on the other hand, in a configuration in which one of the through-holes is within the other through-hole, electrical loss will be lower.

The direction in which one of the first through-hole 9h and the second through-hole 5h is deviated from the other and the degree of the positional deviation are not particularly limited. In the illustrated example, the first through-hole 9h and the second through-hole 5h include portions overlapping each other. However, the positions of the two holes may be deviated so as not to include portions overlapping each other.

### 8. Another Example of Support Structure

As mentioned in Section 6.1, the range, in the peripheral direction, of the joint region where the vibration portion 9 and the outer periphery of the first recess 14 (the outer peripheral region 3b) are joined is not particularly limited. As can be derived from this statement, the vibration portion 9 may be supported, for example, in a cantilever manner. Such an example is shown below.

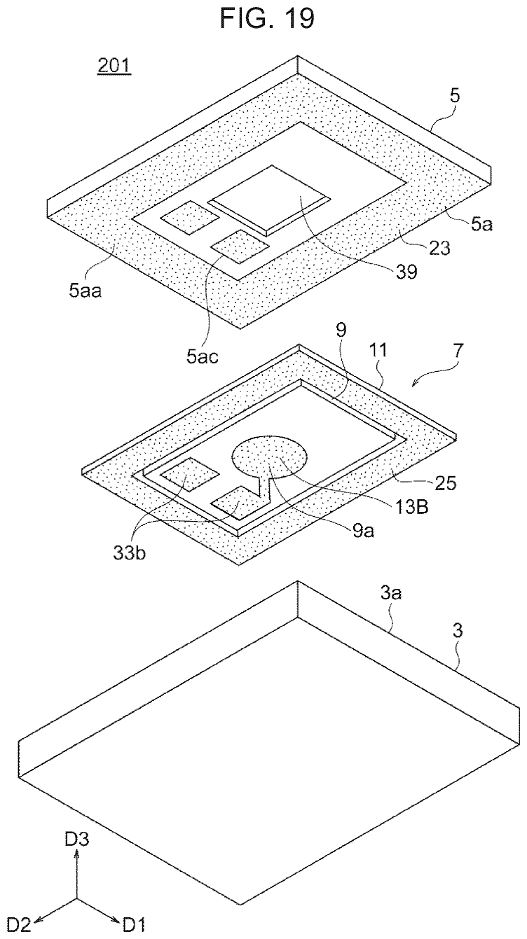

FIG. 18 is an exploded perspective view of a quartz crystal vibrator 201 in which a vibration portion 9 is supported in a cantilever manner, and this figure corresponds to FIG. 1. FIG. 19 is an exploded perspective view of the vibrator 201 from a direction different from the viewing direction in FIG. 18, and this figure corresponds to FIG. 2. FIG. 20 is a cross-sectional view taken along line XX-XX in FIG. 18.

The first-intermediate-side layer 25 stacked on the surface of the intermediate layer 7 facing the first substrate 3 includes two connection electrodes 33b located on one end side of the vibration portion 9 in a specified direction (for example, the D2 direction which is the longitudinal direction) (FIGS. 19 and 20). From a different perspective, the portions of the first-intermediate-side layer 25 stacked on the vibration portion 9 and facing the outer peripheral region 3b of the first recess 14 do not surround the first recess 14 and are located only on one end side of the vibration portion 9.

The first-substrate-side layer 21 stacked on the first surface 3a of the first substrate 3 facing the vibration portion 9 includes two connection pads 21h facing the two connection electrodes 33b (FIGS. 18 and 20). From a different perspective, the portions of the first-substrate-side layer 21 stacked on the outer peripheral region 3b and facing the vibration portion 9 do not surround the first recess 14 and are located only on one end side of the vibration portion 9.

Then, the connection electrodes 33b are joined to the connection pads 21h. For example, the vibration portion 9 faces the outer peripheral region 3b throughout the entire periphery of the first recess 14. However, the vibration portion 9 is away from the outer peripheral region 3b approximately by the distance of the thickness of these conductor layers, except the arrangement regions of the connection electrodes 33b and the connection pads 21h. This configuration enables the vibration portion 9 to be supported by the first substrate 3 in a cantilever manner.

Although the above description is about the support structure by the first substrate 3, the support structure by the second substrate 5 is likewise in a cantilever manner. From a different perspective, one end side of the vibration portion 9 is held between the first substrate 3 and the second substrate 5 so as to be supported in a cantilever manner.

Specifically, the second-intermediate-side layer 27 stacked on the surface of the intermediate layer 7 facing the second substrate 5 includes the two pad electrodes 29 located at one end of the vibration portion 9 (FIGS. 18 and 20) and does not include the inspection electrodes 31. The two pad electrodes 29 are joined to the regions of the second-substrate-side layer 23 stacked on the two pad regions 5ac. With this configuration, the vibration portion 9 is supported in a cantilever manner so as to be away from the second substrate 5 by the distance of the thickness of the pad electrodes 29 and the second-substrate-side layer 23.

The illustrated example does not include the raised portions 5ab. From a different perspective, the second recess 39 does not surround the raised portions 5ab and has approximately the same shape and size as the first recess 14 in perspective plan view. Whether the first recess 14 completely overlaps the second recess 39 in perspective plan view or not, the explanation of the shape, dimensions, and the like of the first recess 14 may be applied to the second recess 39. Note that the vibrator 201 may include the raised portions 5ab, and conversely, the vibrator 1 does not necessarily need to include the raised portions 5ab.

One of the two connection electrodes 33b is connected to the second excitation electrode 13B through a wiring portion (the symbol of which is omitted). The one connection electrode 33b is connected to the second pad electrode 29B immediately above the one connection electrode 33b through the connection conductor 37 (FIG. 20). The other connection electrode 33b may be connected to the first excitation electrode 13A through the connection conductor 37 and the first pad electrode 29A immediately above the other connection electrode 33b, may be connected to the second excitation electrode 13B instead of the first excitation electrode 13A, or may be a dummy electrode that is not connected to either of the excitation electrodes 13.

As can be understood from the above description, the specific number, positions, shapes, and the like of the connection electrodes 33b for achieving a support structure in a cantilever manner are not particularly limited. For example, unlike the illustrated example, the vibration portion 9 may include only one connection electrode 33b extending in the D1 direction. In the illustrated example, the conductors (including the connection conductors 37) of the vibration portion 9 are 180° rotationally symmetric with respect to the center line parallel to the D2 direction. This makes it more likely to achieve the symmetry of vibration. Note that whether the conductors are 180° rotationally symmetric or not, the explanation of the positions, shapes, dimensions, and the like of the pad electrodes 29 and the wiring portions 35 may be applied to the connection electrodes 33b and the wiring portions connected to the connection electrodes 33b.

The specific number, positions, shapes, and the like of the connection pads 21h are also not particularly limited. In the illustrated example, the number, the positions, shapes, and the like of the connection pads 21h are similar to those of the connection electrodes 33b. However, for example, if the connection electrode 33b not connected to the second excitation electrode 13B is a dummy electrode, the first substrate 3 may include one connection pad 21h extending over the two connection electrodes 33b.

In the illustrated example, the vibration portion 9 overlaps the entire first recess 14 when viewed in the D3 direction. From a different perspective, when viewed in the D3 direction, the vibration portion 9 extends from an outside portion of the first recess 14 on one side to an outside portion of the first recess 14 on the other side, in the direction from one end portion at which the vibration portion 9 is supported in a cantilever manner toward the other portion (the free end). From a further different perspective, when viewed in the D3 direction, the first recess 14 does not overlap the other end portion (the free end) mentioned above of the vibration portion 9. However, unlike the illustrated example, the first recess 14 may overlap the free end, and/or the first recess 14 may overlap edge portions of the vibration portion 9 at both ends in the D1 direction as illustrated in FIG. 7 as an example.

Unlike the illustrated example, instead of being held between the first substrate 3 and the second substrate 5, the vibration portion 9 may be separate from the second substrate 5 in its entirety. In this case, for example, the second-substrate-side layer 23 does not include portions stacked on the pad regions 5ac, and the vibration portion 9 is not joined to the second substrate 5. The second substrate 5 may be separate from the vibration portion 9 by forming a larger second recess 39 than the vibration portion 9. Two extension conductors 41 and two external electrodes 15 are provided immediately below the two connection pads 21h in the first substrate 3.

Various kinds of features shown in the example in FIGS. 18 to 20 may be applied as appropriate to vibrators including support structures other than support structures in cantilever manners. For example, in the example in FIGS. 18 to 20, the conductor layer located on the lower surface of the vibration portion 9 is not a solid pattern (not a multifunctional electrode 33) but a pattern including the second excitation electrode 13B, the wiring portion, and the connection electrodes 33b. This configuration may be applied to a vibration portion 9 supported at both ends. For example, the two connection electrodes 33b may be located on both sides of the second excitation electrode 13B in the D2 direction.

### 9. Method of Manufacturing Vibrator

The vibrator 1 (or 201) with the configuration described above may be manufactured by various manufacturing methods. An example is shown below.

FIGS. 12A to 15C are schematic cross-sectional views illustrating an example of a method of manufacturing the vibrator 1. The manufacturing steps basically proceed from FIG. 12A to FIG. 15C.

FIGS. 12A to 15C illustrate, for example, processing steps for a wafer including multiple first substrates 3, a wafer including multiple second substrates 5, and a wafer including multiple intermediate layers 7. However, these figures only illustrate one first substrate 3, one second substrate 5, and one intermediate layer 7 for convenience. Some of the symbols in the following description require reference to other figures for convenience.

These figures are based on an example of a configuration in which the vibration portion 9 is supported by the entire periphery of the first recess 14. The electrical connection between the front and back of the vibration portion 9 is based on the example illustrated in FIG. 6C in which the electrical connection is achieved on a side surface of the vibration portion 9. The second-intermediate-side layer 27 is based on an example of electrode layers including regions having different thicknesses. Note that manufacturing methods for configurations not included in the present example can be inferred from the manufacturing method described below.

As illustrated in FIG. 12A, first, a wafer including multiple first substrates 3 and a wafer including intermediate layers 7 are joined to each other with the first metal layer 17 in between (an example of first joining). More specifically, for example, as illustrated in FIG. 3, the first-substrate-side layer 21 and the first-intermediate-side layer 25 are joined by pressing and heating. In the intermediate layer 7 in this stage, the vibration portion 9 and the frame portion 11 have an integrated form, and conductors other than the first-intermediate-side layer 25 are not present. The first-substrate-side layer 21 extends over the entire surface (first surface 3a) of the first substrate 3 facing the intermediate layer 7. Note that in the case of the vibrator 201 instead of the vibrator 1, the first-substrate-side layer 21 and the first-intermediate-side layer 25 are patterned before the joining.

Next, as illustrated in FIG. 12B, the thickness of the intermediate layer 7 is reduced. This step may include, for example, a step of greatly reducing the thickness by polishing or wet etching and a step of reducing the thickness with high accuracy by a plasma CVM. For example, the final thickness of the intermediate layer 7 according to the frequency intended to be used is achieved through this thickness reducing step. Since the intermediate layer 7 is etched in a wafer state supported by the wafer of the first substrate 3, processing the intermediate layer 7 to makes it extremely thin is easy.

Next, as illustrated in FIG. 12C, the intermediate layer 7 is etched (for example, by wet etching, which applies to other layers unless otherwise specified), so that the outer shapes of the vibration portion 9 and the frame portion 11 are formed (an example of etching). An electrode layer 27c which serves as part of the second-intermediate-side layer 27 is formed. The electrode layer 27c may include a configuration, for example, including the lower layer 27a and the upper layer 27b in the example in FIG. 3. The electrode layer 27c in this stage has the same shape as the planar shapes of the vibration portion 9 and the frame portion 11. Etching of the vibration portion 9 and the frame portion 11 and patterning of the electrode layer 27c may be performed simultaneously, or the former may be performed earlier than the latter.

Next, as illustrated in FIG. 13A, a film of a joint layer 27d serving as the other part of the second-intermediate-side layer 27 is formed. The joint layer 27d, for example, corresponds to the first joint layer 27e and the second joint layer 27f in the example in FIG. 3. The joint layer 27d, for example, is a layer to be joined so as to be directly in contact with the second-substrate-side layer 23 and is composed of a material that improves the strength or functions as a barrier layer (for example, a layered structure of Ti/Au).

Next, as illustrated in FIG. 13B, the joint layer 27d is removed by etching in the region of the upper surface of the vibration portion 9 excluding the regions to serve as the pad electrodes 29 and the inspection electrodes 31, so that part of the electrode layer 27c is exposed.

Next, as illustrated in FIG. 13C, etching is performed to remove the electrode layer 27c, the joint layer 27d, and/or the first metal layer 17 in the region of the vibration portion 9 where the second-intermediate-side layer 27 is not to be present, the region between the vibration portion 9 and the frame portion 11, and the region outside the frame portion 11. In this process, the first excitation electrode 13A and the wiring portions 35 are formed by patterning the electrode layer 27c. The first-substrate-side layer 21 is separated into the inner region 21e and the outer region 21f.

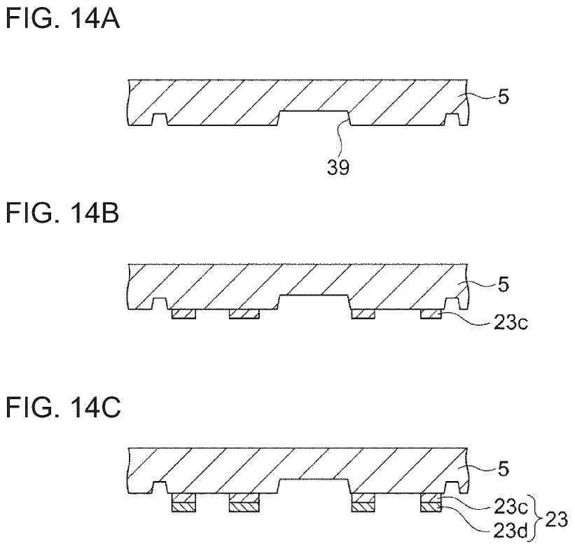

In parallel with the steps illustrated in FIGS. 12A to 13C, the second substrate 5 is formed as illustrated in FIG. 14A. For example, a plate-shaped wafer is etched to form the second recess 39. Note that in the shape of the second recess 39 in plan view in this stage, the frame-shaped region 5aa (the region to be joined to the frame portion 11) is connected to the raised portions 5ab, and another frame-shaped region is located outside the frame-shaped region 5aa.

Next, as illustrated in FIG. 14B, a film of a metal layer 23c serving as part of the second-substrate-side layer 23 is formed and patterned. In the illustrated example, unlike FIG. 3, the metal layer 23c is located only in the regions to be joined to the intermediate layer 7 in the surface (the second surface 5a) of the second substrate 5 facing the intermediate layer 7. For example, the metal layer 23c may include a configuration including the lower layer 23a and the upper layer 23b illustrated in the example in FIG. 3 and may further include a barrier layer.

Next, as illustrated in FIG. 14C, a film of a joint layer 23d serving as the other part of the second-substrate-side layer 23 is formed and patterned. In the illustrated example, as the metal layer 23c mentioned above, the joint layer 23d is located only in the regions to be joined to the intermediate layer 7. The joint layer 23d may be composed of, for example, a material easy to use for joining, such as an AuSn alloy.

Although not specifically illustrated, after forming the second-substrate-side layer 23, the grooves 43 may be formed by etching. In this process, part of the second-substrate-side layer 23 overlapping the regions where the grooves 43 are to be formed is also removed together.

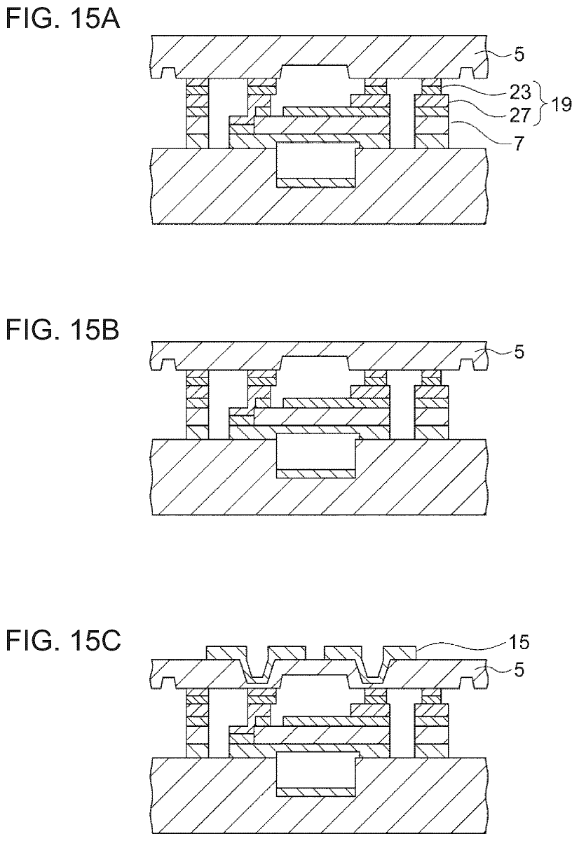

After that, as illustrated in FIG. 15A, the intermediate layer 7 and the second substrate 5 are joined to each other with the second metal layer 19 in between (an example of second joining). More specifically, the second-substrate-side layer 23 and the second-intermediate-side layer 27 are joined by pressing and heating. The second-substrate-side layer 23 and the second-intermediate-side layer 27 may be joined at room temperature by, for example, activating the surfaces of these layers or other methods.

Next, as illustrated in FIG. 15B, the thickness of the second substrate 5 is reduced by polishing or etching. The final thickness of the second substrate 5 is achieved through this process.

Next, as illustrated in FIG. 15C, the second through-holes 5h are formed in the second substrate 5, and then the extension conductors 41 and the external electrodes 15 are formed. After that, although not specifically illustrated, the wafers of the three layers are singulated into individual pieces by being cut with a dicing machine or the like. With this process, the vibrators 1 are completed.

Note that the −D3 side surface of the second substrate 5 includes a frame-shaped recess also outside the frame-shaped region 5aa. When the second through-holes 5h are formed, by forming through-holes from the +D3 side surface in the regions overlapping this recess in plan view, the second substrates 5 are singulated into individual pieces. In this case, the wafers of the three layers need not be cut together with a dicing machine, which improves the productivity. In addition, stress is not exerted on the joint portion between the second substrate 5 and the intermediate layer 7 when cutting with a dicing machine, and thus, the vibrators 1 with high reliability can be provided.

### 10. Summary of Embodiment

As described above, the vibration device (the quartz crystal vibrator 1) according to the embodiment includes the first substrate 3, the second substrate 5, the intermediate layer 7, and the excitation electrodes 13. The first substrate 3 includes the first surface 3a. The second substrate 5 includes the second surface 5a facing the first surface 3a. The intermediate layer 7 is located between the first surface 3a and the second surface 5a. The first surface 3a includes the first recess 14. The intermediate layer 7 includes the vibration portion 9 and the frame portion 11. The vibration portion 9 includes the excitation portion 9a at which the excitation electrodes 13 are located. The excitation portion 9a faces (at least part of) the first recess 14. The frame portion 11 surrounds the vibration portion 9 in plan view and is joined to the first surface 3a and the second surface 5a. The frame portion 11 includes layers composed of the same materials as the layers included in the vibration portion 9. The outer edge of the vibration portion 9 is away from the frame portion 11 throughout the entire periphery. The vibration portion 9 is joined to the outer peripheral region 3b of the first recess 14 on the first surface 3a.

With this configuration, as described in the overview of the embodiment, for example, the probability that the vibration of the vibration portion 9 is leaked to the frame portion 11 is reduced. In addition, since the vibration portion 9 is supported by the outer peripheral region 3b, the support structure is simplified, and/or the degree of freedom in designing the support position is improved.

The vibration portion 9 may be joined to the outer peripheral region 3b over an angular range of 180° or more around the center (the geometric center) of the vibration portion 9 in plan view.

In this case, it can be said that the vibration portion 9 is supported over a wide range in its peripheral direction. Hence, for example, the warp and/or deflection of the vibration portion 9 will be reduced, and the characteristics of the vibrator 1 will be stabilized.

The vibration device (the vibrator 1) may include the first metal layer 17 and the second metal layer 19. The first metal layer 17 may be interposed between and join the vibration portion 9 and the first surface 3a and may be interposed between and join the frame portion 11 and the first surface 3a. The second metal layer 19 may be interposed between and join the frame portion 11 and the second surface 5a.

In this case, for example, the joining is easier than in a configuration in which the frame portion 11 and the second surface 5a are directly joined. For example, the metal layers used for the electrodes such as the excitation electrodes 13 can be used for the joining.

The vibration device (the vibrator 1) may include the pad electrodes 29. The pad electrodes 29 may be located on the side of the vibration portion 9 facing the second surface 5a and may be electrically connected to the excitation electrodes 13. The second surface 5a may include the frame-shaped region 5aa, the pad regions 5ac, and the second recess 39. The frame-shaped region 5aa may be joined to the frame portion 11. The pad regions Sac may be joined to the pad electrodes 29. The second recess 39 may be surrounded by the frame-shaped region 5aa, surround the pad regions 5ac, and face the excitation portion 9a.

For example, as described above, this configuration makes the vibration of the excitation portion 9a easier and increases the contact pressure when the pad electrodes 29 and the second-substrate-side layer 23 are joined.

The second surface 5a may include the raised portions 5ab surrounded by the second recess 39. Each raised portion 5ab may include the top surface including the pad region 5ac to be joined to the corresponding pad electrode 29. The top surfaces of the raised portions 5ab or the bottom surface of the second recess 39 may include the grooves 43 surrounding the pad regions 5ac and the pad electrodes 29 in perspective plan view.

This configuration, for example, reduces the probability of the occurrence of an unintended short circuit as described with reference to FIGS. 4, 10, and 11. The combination with the raised portions 5ab improves the benefit of insulating the portions on the pad regions 5ac of the second-substrate-side layer 23 from the other portions of the second-substrate-side layer 23.

The vibration device (the vibrator 1) may include the second metal layer 19 stacked on the second surface 5a. The second metal layer 19 may face an entirety of the excitation portion 9a and may also face the outer edge of the vibration portion 9, the frame portion 11, and the gap between the vibration portion 9 and the frame portion 11. From a different perspective, for example, the second metal layer 19 may extend approximately over the entire second surface 5a.

This configuration, for example, makes it more likely that the second metal layer 19 functions as a shield and/or a reinforcement material. This also reduces the probability that a gas is emitted from the second substrate 5 to the space around the vibration portion 9 in the manufacturing process or the like.

The vibration device (the vibrator 1) may include the first metal layer 17 and the second metal layer 19. The first metal layer 17 may be located between and in contact with the vibration portion 9 and the first surface 3a and may be interposed between and in contact with the frame portion 11 and the first surface 3a. The second metal layer 19 may be located between and in contact with the frame portion 11 and the second surface 5a. The second substrate 5 may be thinner than the first substrate 3. The second metal layer 19 may be thicker than the first metal layer 17.

In this case, for example, since the first substrate 3 is thicker than the second substrate 5, the external stress is less likely to be transmitted to the vibration portion 9 supported by the outer periphery of the first recess 14. This reduces the probability of degradation in the characteristics of the vibration portion 9. From a different perspective, the thin second substrate 5 leads to thickness reduction while the characteristics of the vibration portion 9 are maintained. The relatively thick second metal layer 19 reinforces the strength of the relatively thin second substrate 5. This improves the overall strength of the vibrator 1.

The vibration portion 9 may have a uniform thickness from (at least part of) the region facing the first recess 14 to (at least part of) the region facing the outer peripheral region 3b. In other words, the vibration portion 9 may include a portion having a uniform thickness and spanning the boundary between the first recess 14 and the outer peripheral region 3b. For example, the entire vibration portion 9 may have a uniform thickness. Note that in this statement, the particular portions in the vibration portion 9 such as the first through-holes 9h may be excluded from the consideration.

In the vibration portion 9, stress tends to be concentrated at the boundary between the first recess 14 and the outer peripheral region 3b. However, in the configuration mentioned in the previous paragraph, the stress concentration at the boundary mentioned above is lower than in a configuration in which the region of the vibration portion 9 facing the first recess 14 is thinner than the region of the vibration portion 9 facing the outer peripheral region 3b (this configuration is also included in the techniques according to the present disclosure). This, for example, improves the resistance to shocks. This also reduces the change in the temperature characteristic due to stress.

The vibration device (the vibrator 1) may include the third metal layer (the first-intermediate-side layer 25, or from a different perspective, the multifunctional electrode 33) stacked on the first surface 3a side of the vibration portion 9. The first-intermediate-side layer 25 may span the boundary between the first recess 14 and the outer peripheral region 3b in perspective plan view, and the portion spanning the boundary may extend over an angular range of 30° or more, 45° or more, 75° or more, 100° or more, 150° or more, or 180° or more of a turn around the center (the geometric center) of the first recess 14. The portion spanning the boundary need not be continuous, and a configuration in which the total angular ranges of the regions is within the above angular ranges is also included in the present disclosure.

In this case, for example, the portion of the first-intermediate-side layer 25 interposed between the boundary and the vibration portion 9 is longer than in a configuration in which the multifunctional electrode 33 does not have a solid pattern, and in which a wiring portion extending from the second excitation electrode 13B spans the boundary between the first recess 14 and the outer peripheral region 3b (this configuration is also included in the techniques according to the present disclosure). In addition, the first-intermediate-side layer 25 will have a benefit of relieving the stress generated in the vibration portion 9 due to the boundary. This, for example, reduces the probability that an unintentional stress is generated in the vibration portion 9, which in turn provides the benefit of improving the characteristics of the vibration portion 9 and/or improving the resistance to shocks.

The vibration device (the vibrator 1) may include the first metal layer 17 interposed between and joining the intermediate layer 7 and the first surface 3a. The first metal layer 17 may include the third metal layer stacked on the vibration portion 9 and the frame portion 11 (for example, the first-intermediate-side layer 25 (or the lower layer 25a or the upper layer 25b) in FIG. 3). In the first-intermediate-side layer 25, the portion stacked on the vibration portion 9 (the multifunctional electrode 33) and the portion stacked on the frame portion 11 may be composed of the same material and have the same thickness, and the first-intermediate-side layer 25 may include a portion stacked on the excitation portion 9a. The same material in this statement need not be completely identical and includes materials having inevitable differences in terms of material and manufacturing and differences in the concentration of impurities. The same thickness in the above statement need not be completely identical, and for example, denotes that the difference between the thickness (for example, the average value) of the portion stacked on the frame portion 11 and the thickness (for example, average value) of the portion stacked on the vibration portion 9 is within ±5% of the latter thickness.

In this case, for example, the first-intermediate-side layer 25 (or the lower layer 25a or the upper layer 25b) used for the second excitation electrode 13B is also used for the joining of the frame portion 11 and the first substrate 3. This, for example, simplifies the configuration.

The vibration device (the vibrator 1) may include the first metal layer 17 located between and in contact with the intermediate layer 7 and the first surface 3a. The first metal layer 17 may be thinner than the excitation portion 9a.

In this case, for example, the thin first metal layer 17 contributes to the thickness reduction of the vibrator 1. The first recess 14 ensures a sufficient distance between the excitation portion 9a and the first surface 3a (the bottom surface of the first recess 14) in the embodiment, dispensing with a thick first metal layer 17 to keep the distance between the excitation portion 9a and the first surface 3a. This makes it possible to reduce the thickness of the first metal layer 17. Note that as already mentioned, in a configuration using thickness shear vibration, the excitation portion 9a adapted to high frequency is extremely thin. When a first metal layer 17 thinner than such a thin excitation portion 9a is used, the benefit mentioned above increases.

An excitation electrode 13 (the first excitation electrode 13A) may be located on the surface of the vibration portion 9 facing the second substrate 5 and may be within the first recess 14 in perspective plan view.

This configuration, for example, reduces the probability that the vibration of the excitation portion 9a is restricted by an edge portion of the first recess 14 or reduces the degree of the restriction. This, for example, results in an improvement in the characteristics of the vibration portion 9.

The vibration device (the vibrator 1) may include the fourth metal layer (the first-substrate-side layer 21) stacked on the bottom surface of the first recess 14.

This configuration, for example, improves the benefit as a shield and/or a reinforcement material provided by the first-substrate-side layer 21. This, for example, also reduces the gas emitted from the first substrate 3 to the space surrounding the vibration portion 9 in a manufacturing process.

The vibration device (the vibrator 1) may include the fourth metal layer (the first-substrate-side layer 21) stacked on the first substrate 3 and extending from the side surfaces of the first recess 14 to the outer peripheral region 3b (FIG. 4).

This configuration, for example, provides the benefit the same as and/or similar to the aforementioned benefit for the case in which the first-substrate-side layer 21 is stacked on the bottom surface of the first recess 14. For example, since the first-substrate-side layer 21 is interposed between the edge portions of the first recess 14 and the vibration portion 9, the stress generated in the vibration portion 9 due to the edge portions mentioned above will be reduced.

The outer edge of the frame portion 11 and the outer edge of the second substrate 5 may be located inside the outer edge of the first substrate 3 throughout the entire periphery in perspective plan view.

This configuration, for example, enables the outer peripheral surfaces of the first substrate 3 to protect the outer peripheral surfaces of the frame portion 11 and the second substrate 5 against contact from the outer peripheral sides. Hence, for example, the relatively thick first substrate 3 not only reduces the probability of deformation of the vibration portion 9 joined to the first substrate 3 as already mentioned but also improves the resistance to contact with the vibrator 1 from the outer peripheral sides. This, for example, also makes it easier to cut the first substrate 3 from the second substrate 5 side with a dicing machine in a manufacturing process.

The vibration portion 9 and the excitation electrodes 13 may include a configuration to use thickness shear vibration. The first recess 14 may have an elliptical shape with the longitudinal direction corresponding to the direction of the thickness shear vibration in plan view.

This means that the first recess 14 has a shape similar to the shape in which the energy of the thickness shear vibration is confined. This configuration, for example, reduces the area of the first recess 14, making it easier to ensure sufficient strength for the first substrate 3 while maintaining the characteristics of the vibration portion 9.

The side surfaces of the vibration portion 9 may include an inclined surface inclined outward of the vibration portion 9 as it extends toward the first substrate 3.

This configuration can, for example, increase the joint area between the vibration portion 9 and the first substrate 3. For example, when the connection layer 38 (which may be formed together with the second-intermediate-side layer 27) extending from the +D3 side of the vibration portion 9 and stacked on a side surface of the vibration portion 9 is formed to electrically connect the second-intermediate-side layer 27 and the first metal layer 17, the film formation of the connection layer 38 is easy. From a different perspective, this configuration improves the reliability of the electrical connection by the connection layer 38.

The distance between the vibration portion 9 and the frame portion 11 may be the length (n×λ/4) obtained by multiplying, by a natural number, ¼ of the wavelength of at least one vibration, as unnecessary vibration in the excitation portion 9a, selected from the group consisting of flexural vibration, thickness vibration, and contour shear vibration.

This configuration, for example, reduces the effects of unnecessary vibration. Part of the vibration of the vibration portion 9 reaches the frame portion 11 through the first substrate 3. This vibration is reflected on the frame portion 11 and returns to the vibration portion 9, which reduces the loss of vibration and contributes to efficient generation of vibration.

The vibration portion 9 may include the first through-holes 9h in which the conductors (the connection conductors 37) electrically connecting the first substrate 3 side of the vibration portion 9 and the second substrate 5 side of the vibration portion 9 are located. One substrate out of the first substrate 3 and the second substrate 5 (the second substrate 5 in the illustrated example) may include the second through-holes 5h in which the conductors (the extension conductors 41) electrically connecting the intermediate layer 7 side of the one substrate and the side of the intermediate layer 7 opposite to the one substrate are located. The first through-holes 9h and the second through-holes 5h may include portions not overlapping each other in perspective plan view.

In this case, as explained with reference to FIG. 11, the structural strength of the vibrator 1 will be improved.

The vibration portion 9 may include the first through-holes 9h in which the conductors electrically connecting the first substrate 3 side of the vibration portion 9 and the second substrate 5 side of the vibration portion 9 are located. The first through-hole 9h may have a shape in which the length in the first direction (the D1 direction) is longer than the length in the second direction (the D2 direction) orthogonal to the first direction in plan view of the vibration portion 9. The first through-holes 9h may have a tapered shape the diameter of which decreases toward the first substrate 3. The taper angle θ1 in the cross section orthogonal to the first direction may be larger than the taper angle θ2 in the cross section orthogonal to the second direction.

In this case, for example, as already mentioned, as for the inclination angle of the inner surfaces of the first through-hole 9h relative to the +D3 the side surface of the vibration portion 9, the average of the two inner surfaces in the vertical cross section orthogonal to the longitudinal direction (the D1 direction) is set to be less than the average of the two inner surfaces in the vertical cross section orthogonal to the lateral direction. Hence, for example, when a film of a conductor is formed from the +D3 side, in general, the film can be formed more easily on the inner surfaces in the vertical cross section orthogonal to the longitudinal direction. Since the inner surfaces in the vertical cross section as mentioned above are sufficiently long in plan view, the reliability of electrical connection is high as a whole.

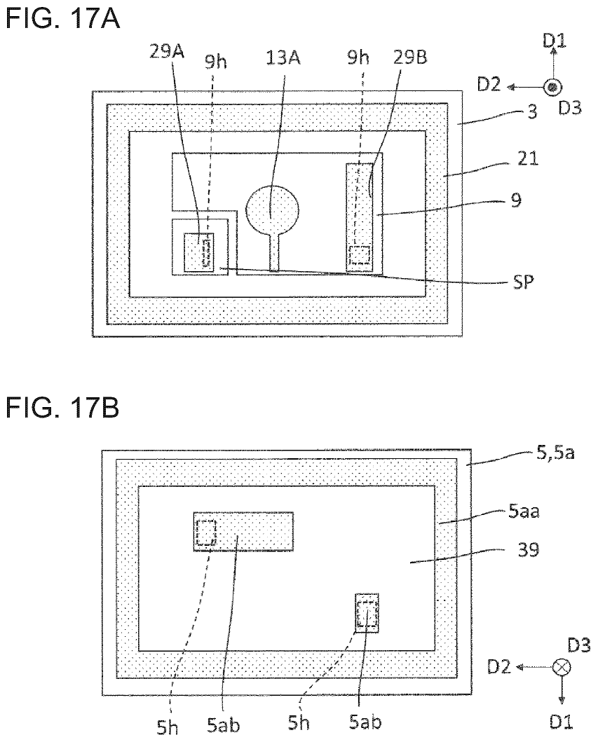

As illustrated in FIG. 17A, the vibration portion 9 may include a separate portion SP which is separated from the other portion of the vibration portion 9. The separate portion SP is joined to the first substrate 3 in the same and/or similar manner as/to the manner of joining the vibration portion 9 in another example to the first substrate 3.

The first excitation electrode 13A is provided with a narrow portion extending from a portion overlapping the first recess 14 to the outside in plan view. A first pad electrode 29A is located on the +D3 side surface of the separate portion SP. The first pad electrode 29A is electrically connected to the first-intermediate-side layer 25 through the first through-hole 9h.

As illustrated in FIG. 17B, the area of the raised portion 5ab associated with the first pad electrode 29A (in other words, the electrode electrically connected to the first excitation electrode 13A) is larger than the area of the raised portion 5ab associated with the second pad electrode 29B. Specifically, the raised portion 5ab is formed to be continuous in a region corresponding to the narrow portion and the first pad electrode 29A. Part of the second-substrate-side layer 23 located on the raised portion 5ab electrically connects the narrow portion and the first pad electrode 29A.

This configuration reduces the area of the narrow portion. This, in turn, reduces the capacitance formed by the first-intermediate-side layer 25 and the narrow portion, leading to the vibrator 1 with excellent characteristics.

Although the thickness of the intermediate layer 7 is reduced after the intermediate layer 7 is joined to the first substrate 3 in the example described above, use of an intermediate layer 7 in the form of a film thinned in advance eliminates the thickness adjustment step after joining.

The method of manufacturing the quartz crystal vibrator 1 may include, for example, first joining (FIG. 12A), etching (FIG. 12C), and second joining (FIG. 15A). In the first joining, the intermediate layer 7 including the vibration portion 9 and the frame portion 11 in an integrated form is joined to the first surface 3a including the first recess 14. In the etching, the intermediate layer 7 is etched after the first joining, and the entire outer edge of the vibration portion 9 is separated from the frame portion 11. In the second joining, the second surface Sa is joined to the intermediate layer 7 after the etching.

In this case, for example, since the intermediate layer 7 including the vibration portion 9 and the frame portion 11 in an integrated form is stacked on the first substrate 3, and then, the vibration portion 9 is processed, as mentioned in the overview of the embodiment, the warp and/or deflection of the vibration portion 9 will be reduced, and the characteristics of the vibrator 1 will be stabilized.

In the embodiment described above, the quartz crystal vibrator 1 is an example of the vibration device. The first-intermediate-side layer 25 is an example of the third metal layer. The first-substrate-side layer 21 is an example of the fourth metal layer. The D1 direction is an example of the first direction. The D2 direction is an example of the second direction.

The techniques according to the present disclosure are not limited to the embodiment described above and may be implemented in various configurations.

For example, the vibration device is not limited to vibrators. For example, the vibration device may be an oscillator including an oscillation circuit configured to apply a voltage to the vibration portion to generate an oscillation signal. In this case, for example, an integrated circuit (IC) may be mounted on either side of the first substrate and/or the second substrate, meaning the inner side or the outer side of the vibration device. Alternatively, an oscillation circuit may be formed by injecting dopant into the first substrate and/or the second substrate composed of a semiconductor and forming electrodes on the substrates. Alternatively, the first substrate and/or the second substrate may be composed of a multilayer substrate and include a built-in oscillation circuit. For example, the vibration device may be used for purposes other than generating an oscillation signal, such as filtering.

The following concepts can be extracted from the present disclosure.

### (Concept 1)

A vibration device including:
a first substrate including a first surface;
a second substrate including a second surface facing the first surface;
an intermediate layer located between the first surface and the second surface; and
an excitation electrode, in which
the first surface includes a first recess,
the intermediate layer includes:
   a vibration portion including an excitation portion at which the excitation electrode is located and that faces the first recess; and
   a frame portion surrounding the vibration portion in plan view and joined to the first surface and the second surface,
the frame portion includes a layer composed of a same material as a layer included in the vibration portion,
an entire periphery of an outer edge of the vibration portion is away from the frame portion, and
the vibration portion is joined to an outer peripheral region of the first recess on the first surface.

### (Concept 2)

The vibration device according to concept 1, further including:
a first metal layer interposed between and joining the vibration portion and the first surface and interposed between and joining the frame portion and the first surface; and
a second metal layer interposed between and joining the frame portion and the second surface.

### (Concept 3)

The vibration device according to concept 1 or 2, further including
a pad electrode located on a side of the vibration portion facing the second surface and electrically connected to the excitation electrode, in which
the second surface includes:
   a frame-shaped region joined to the frame portion;
   a pad region joined to the pad electrode; and
   a second recess surrounded by the frame-shaped region, surrounding the pad region, and facing the excitation portion.

### (Concept 4)

The vibration device according to concept 3, in which
the second surface includes a raised portion surrounded by the second recess,
the raised portion includes a top surface including the pad region, and
the top surface of the raised portion or a bottom surface of the second recess includes a groove surrounding the pad region and the pad electrode in perspective plan view.

### (Concept 5)

The vibration device according to any one of concepts 1 to 4, further including
a second metal layer stacked on the second surface, in which
the second metal layer faces an entirety of the excitation portion and faces the outer edge of the vibration portion, the frame portion, a gap between the vibration portion and the frame portion.

### (Concept 6)

The vibration device according to any one of concepts 1 to 5, further including:
a first metal layer located between and in contact with the vibration portion and the first surface and located between and in contact with the frame portion and the first surface; and
a second metal layer located between and in contact with the frame portion and the second surface, in which
the second substrate is thinner than the first substrate, and
the second metal layer is thicker than the first metal layer.

### (Concept 7)

The vibration device according to any one of concepts 1 to 6, in which
the vibration portion has a uniform thickness from a region facing the first recess to a region facing the outer peripheral region.

### (Concept 8)

The vibration device according to any one of concepts 1 to 7, further including
a first metal layer interposed between and joining the intermediate layer and the first surface, in which
the first metal layer includes a third metal layer stacked on the vibration portion and the frame portion, and
in the third metal layer, a portion stacked on the vibration portion and a portion stacked on the frame portion are composed of a same material and have a same thickness, and the third metal layer includes a portion stacked on the excitation portion.

### (Concept 9)

The vibration device according to any one of concepts 1 to 8, further including
a first metal layer located between and in contact with the intermediate layer and the first surface, in which
the first metal layer is thinner than the excitation portion.

### (Concept 10)

The vibration device according to any one of concepts 1 to 9, in which
the excitation electrode is located on a surface of the vibration portion facing the second substrate and is within the first recess in perspective plan view.

### (Concept 11)

The vibration device according to any one of concepts 1 to 10, further including
a fourth metal layer stacked on a bottom surface of the first recess.

### (Concept 12)

The vibration device according to any one of concepts 1 to 11, further including
a fourth metal layer stacked on the first substrate and extending from a side surface of the first recess over the outer peripheral region.

### (Concept 13)

The vibration device according to any one of concepts 1 to 12, in which
an entire periphery of an outer edge of the frame portion and an entire periphery of an outer edge of the second substrate are located inside an outer edge of the first substrate in perspective plan view.

### (Concept 14)

The vibration device according to any one of concepts 1 to 13, in which
the vibration portion and the excitation electrode are configured to use thickness shear vibration, and
the first recess has an elliptical shape with a longitudinal direction corresponding to a direction of thickness shear vibration in plan view.

### (Concept 15)

The vibration device according to any one of concepts 1 to 14, in which
a side surface of the vibration portion includes an inclined surface inclined outward of the vibration portion as the inclined surface extends toward the first substrate.

### (Concept 16)

The vibration device according to any one of concepts 1 to 15, in which
a distance between the vibration portion and the frame portion is a length obtained by multiplying, by a natural number, ¼ of a wavelength of at least one vibration, as unnecessary vibration in the excitation portion, selected from the group consisting of flexural vibration, thickness vibration, and contour shear vibration.

### (Concept 17)

The vibration device according to any one of concepts 1 to 16, in which
the vibration portion includes a first through-hole in which a conductor is located, the conductor electrically connecting a side of the vibration portion facing the first substrate and a side of the vibration portion facing the second substrate,
one substrate out of the first substrate and the second substrate includes a second through-hole in which a conductor is located, the conductor electrically connecting a side of the one substrate facing the intermediate layer and a side of the one substrate opposite to the intermediate layer, and
the first through-hole and the second through-hole include portions not overlapping each other in perspective plan view.

### (Concept 18)

The vibration device according to any one of concepts 1 to 17, in which
the vibration portion includes a first through-hole in which a conductor is located, the conductor electrically connecting a side of the vibration portion facing the first substrate and a side of the vibration portion facing the second substrate,
the first through-hole has a shape
   in which a length in a first direction is longer than a length in a second direction orthogonal to the first direction in plan view of the vibration portion, and
   that is in a form of a taper a diameter of which decreases toward the first substrate, and
a taper angle in a cross section orthogonal to the first direction is larger than a taper angle in a cross section orthogonal to the second direction.

### (Concept 19)

The vibration device according to concept 8, in which
the frame portion and the vibration portion are composed of a same material and have approximately a same thickness,
the excitation electrode is located on each of a side of the vibration portion facing the first substrate and a side of the vibration portion facing the second substrate, and
the third metal layer includes the excitation electrode located on the side of the vibration portion facing the first substrate.

### (Concept 20)

The vibration device according to any one of concepts 1 to 19, in which
the vibration portion is joined to the outer peripheral region over an angular range of 180° or more around a center of the vibration portion in plan view.

### (Concept 21)

The vibration device according to any one of concepts 1 to 20, further including
a third metal layer stacked on a side of the vibration portion facing the first surface, in which
the third metal layer spans a boundary between the first recess and the outer peripheral region in perspective plan view, and a portion of the third metal layer spanning the boundary extends over an angular range of 180° or more around a center of the first recess.

### (Concept 22)

A method of manufacturing the vibration device according to any one of concepts 1 to 21, including:
first joining of joining the intermediate layer including the vibration portion and the frame portion in an integrated form, to the first surface including the first recess;
an etching step of etching the intermediate layer after the first joining and separating the entire periphery of the outer edge of the vibration portion from the frame portion; and
second joining of joining the second surface to the intermediate layer after the etching step.

Concepts other than above can be extracted from the present disclosure. For example, although the concept 1 mentioned above requires the frame portion and the vibration portion to include layers composed of the same material, concepts that do not require layers of the same material may be extracted. The concepts extracted in such a manner may feature the items mentioned in the concepts 2 to 21.

### REFERENCE SIGNS

1 quartz crystal vibrator (vibration device)
3 first substrate
3a first surface
3b outer peripheral region
5 second substrate
5a second surface
7 intermediate layer
9 vibration portion
9a excitation portion
11 frame portion
13 excitation electrode
14 first recess

1. A vibration device comprising:
a first substrate comprising a first surface;
a second substrate comprising a second surface facing the first surface;
an intermediate layer located between the first surface and the second surface; and
an excitation electrode, wherein
the first surface comprises a first recess,
the intermediate layer comprises:
a vibration portion comprising an excitation portion at which the excitation electrode is located and that faces the first recess; and
a frame portion surrounding the vibration portion in plan view and joined to the first surface and the second surface,
the frame portion comprises a layer composed of a same material as a layer comprised in the vibration portion,
an entire periphery of an outer edge of the vibration portion is away from the frame portion, and
the vibration portion is joined to an outer peripheral region of the first recess on the first surface.

2. The vibration device according to claim 1, further comprising:
a first metal layer interposed between and joining the vibration portion and the first surface and interposed between and joining the frame portion and the first surface; and
a second metal layer interposed between and joining the frame portion and the second surface.

3. The vibration device according to claim 1, further comprising
a pad electrode located on a side of the vibration portion facing the second surface and electrically connected to the excitation electrode, wherein
the second surface comprises:
a frame-shaped region joined to the frame portion;
a pad region joined to the pad electrode; and
a second recess surrounded by the frame-shaped region, surrounding the pad region, and facing the excitation portion.

4. The vibration device according to claim 3, wherein
the second surface comprises a raised portion surrounded by the second recess,
the raised portion comprises a top surface comprising the pad region, and
the top surface of the raised portion or a bottom surface of the second recess comprises a groove surrounding the pad region and the pad electrode in perspective plan view.

5. The vibration device according to claim 1, further comprising
a second metal layer stacked on the second surface, wherein
the second metal layer faces an entirety of the excitation portion and faces the outer edge of the vibration portion, the frame portion, and a gap between the vibration portion and the frame portion.

6. The vibration device according to claim 1, further comprising:
a first metal layer located between and in contact with the vibration portion and the first surface and located between and in contact with the frame portion and the first surface; and
a second metal layer located between and in contact with the frame portion and the second surface, wherein
the second substrate is thinner than the first substrate, and
the second metal layer is thicker than the first metal layer.

7. The vibration device according to claim 1, wherein
the vibration portion has a uniform thickness from a region facing the first recess to a region facing the outer peripheral region.

8. The vibration device according to claim 1, further comprising
a first metal layer interposed between and joining the intermediate layer and the first surface, wherein
the first metal layer comprises a third metal layer stacked on the vibration portion and the frame portion, and
in the third metal layer, a portion stacked on the vibration portion and a portion stacked on the frame portion are composed of a same material and have a same thickness, and the third metal layer comprises a portion stacked on the excitation portion.

9. The vibration device according to claim 1, further comprising
a first metal layer located between and in contact with the intermediate layer and the first surface, wherein
the first metal layer is thinner than the excitation portion.

10. The vibration device according to claim 1, wherein
the excitation electrode is located on a surface of the vibration portion facing the second substrate and is within the first recess in perspective plan view.

11. The vibration device according to claim 1, further comprising
a fourth metal layer stacked on a bottom surface of the first recess.

12. The vibration device according to claim 1, further comprising
a fourth metal layer stacked on the first substrate and extending from a side surface of the first recess over the outer peripheral region.

13. The vibration device according to claim 1, wherein
an entire periphery of an outer edge of the frame portion and an entire periphery of an outer edge of the second substrate are located inside an outer edge of the first substrate in perspective plan view.

14. The vibration device according to claim 1, wherein
the vibration portion and the excitation electrode are configured to use thickness shear vibration, and
the first recess has an elliptical shape with a longitudinal direction corresponding to a direction of thickness shear vibration in plan view.

15. The vibration device according to claim 1, wherein
a side surface of the vibration portion comprises an inclined surface inclined outward of the vibration portion as the inclined surface extends toward the first substrate.

16. The vibration device according to claim 1, wherein
a distance between the vibration portion and the frame portion is a length obtained by multiplying, by a natural number, ¼ of a wavelength of at least one vibration, as unnecessary vibration in the excitation portion, selected from the group consisting of flexural vibration, thickness vibration, and contour shear vibration.

17. The vibration device according to claim 1, wherein
the vibration portion comprises a first through-hole in which a conductor is located, the conductor electrically connecting a side of the vibration portion facing the first substrate and a side of the vibration portion facing the second substrate,
one substrate out of the first substrate and the second substrate comprises a second through-hole in which a conductor is located, the conductor electrically connecting a side of the one substrate facing the intermediate layer and a side of the one substrate opposite to the intermediate layer, and
the first through-hole and the second through-hole comprise portions not overlapping each other in perspective plan view.

18. The vibration device according to claim 1, wherein
the vibration portion comprises a first through-hole in which a conductor is located, the conductor electrically connecting a side of the vibration portion facing the first substrate and a side of the vibration portion facing the second substrate,
the first through-hole has a shape
in which a length in a first direction is longer than a length in a second direction orthogonal to the first direction in plan view of the vibration portion, and
that is in a form of a taper a diameter of which decreases toward the first substrate, and
a taper angle in a cross section orthogonal to the first direction is larger than a taper angle in a cross section orthogonal to the second direction.

19. The vibration device according to claim 8, wherein
the frame portion and the vibration portion are composed of a same material and have approximately a same thickness,
the excitation electrode is located on each of a side of the vibration portion facing the first substrate and a side of the vibration portion facing the second substrate, and
the third metal layer comprises the excitation electrode located on the side of the vibration portion facing the first substrate.

20. The vibration device according to claim 1, wherein
the vibration portion is joined to the outer peripheral region over an angular range of 180° or more around a center of the vibration portion in plan view.

21. The vibration device according to claim 1, further comprising
a third metal layer stacked on a side of the vibration portion facing the first surface, wherein
the third metal layer spans a boundary between the first recess and the outer peripheral region in perspective plan view, and a portion of the third metal layer spanning the boundary extends over an angular range of 180° or more around a center of the first recess.

22. A method of manufacturing the vibration device according to claim 1, comprising:
first joining of joining the intermediate layer comprising the vibration portion and the frame portion in an integrated form, to the first surface comprising the first recess;
an etching step of etching the intermediate layer after the first joining and separating the entire periphery of the outer edge of the vibration portion from the frame portion; and
second joining of joining the second surface to the intermediate layer after the etching step.
